(19) United States
(12) Patent Application Publication
(10) Pub. No.: US 2024/0324366 A1
(43) Pub. Date: Sep. 26, 2024

(54) DISPLAY APPARATUS

(71) Applicant: Samsung Display Co., Ltd., Yongin-si (KR)

(72) Inventors: Sunghwan Kim, Yongin-si (KR); Wonkyu Kwak, Yongin-si (KR); Daehyun Kim, Yongin-si (KR); Heyjin Shin, Yongin-si (KR); Changkyu Jin, Yongin-si (KR)

(73) Assignee: Samsung Display Co., Ltd., Yongin-si (KR)

(21) Appl. No.: 18/612,089

(22) Filed: Mar. 21, 2024

(30) Foreign Application Priority Data
Mar. 24, 2023 (KR) 10-2023-0039126
Jul. 31, 2023 (KR) 10-2023-0099829

(51) Int. Cl. H10K 59/131; H10K 59/124

(52) U.S. Cl. CPC H10K 59/131; H10K 59/124

(57) ABSTRACT

A display apparatus includes a pixel electrode in which an emission area is defined, a first horizontal conductive layer extending in a first direction, a first vertical conductive layer extending in a second direction intersecting the first direction, and intersecting the first horizontal conductive layer, a second vertical conductive layer extending in the second direction and intersecting the first horizontal conductive layer, and an insulating layer disposed between the first horizontal conductive layer and the first vertical conductive layer and between the first horizontal conductive layer and the second vertical conductive layer. A first contact hole through which the first vertical conductive layer contacts the first horizontal conductive layer is defined in the insulating layer, and the first contact hole is spaced apart from the emission area.

### CROSS-REFERENCE TO RELATED APPLICATION(S)

This application claims priority and benefits of Korean Patent Application No. 10-2023-0039126, filed on Mar. 24, 2023, and Korean Patent Application No. 10-2023-0099829, filed on Jul. 31, 2023, in the Korean Intellectual Property Office, the entire contents of which are incorporated herein by reference.

### BACKGROUND

### 1. Technical Field

One or more embodiments relate to a display apparatus.

### 2. Description of the Related Art

In recent years, applications of display apparatuses have diversified. Also, due to their relatively small thickness and light weight, the usage of the display apparatuses has increased.

In such display apparatuses, thin-film transistors, capacitors, and wirings may be arranged in each pixel to control the luminance or the like of each pixel. As display apparatuses are utilized in various ways, various types of display apparatuses are being designed.

### SUMMARY

When contact holes through which wirings arranged on different layers contact each other overlap emission areas of some pixels, light-emitting characteristics between pixels may vary according to viewing angles.

One or more embodiments include a display apparatus providing a high-quality image by reducing a difference in light-emitting characteristics between pixels.

However, embodiments of the disclosure are not limited to those set forth herein. The above and other embodiments will become more apparent to one of ordinary skill in the art to which the disclosure pertains by referencing the detailed description of the disclosure given below.

According to one or more embodiments, a display apparatus may include a pixel electrode in which an emission area is defined, a first horizontal conductive layer extending in a first direction, a first vertical conductive layer extending in a second direction intersecting the first direction, and intersecting the first horizontal conductive layer, a second vertical conductive layer extending in the second direction and intersecting the first horizontal conductive layer, and an insulating layer disposed between the first horizontal conductive layer and the first vertical conductive layer and between the first horizontal conductive layer and the second vertical conductive layer. A first contact hole through which the first vertical conductive layer contacts the first horizontal conductive layer is defined in the insulating layer, and the first contact hole is spaced apart from the emission area.

In an area where the first horizontal conductive layer and the second vertical conductive layer intersect each other, the insulating layer may cover the first horizontal conductive layer.

The area where the first horizontal conductive layer and the second vertical conductive layer intersect each other may be spaced apart from a center portion of the emission area.

The display apparatus may further include a second horizontal conductive layer extending in the first direction and intersecting the first vertical conductive layer and the second vertical conductive layer. A second contact hole through which the second horizontal conductive layer contacts the second vertical conductive layer may be defined in the insulating layer, and the second contact hole may be spaced apart from the emission area.

A third contact hole through which the second horizontal conductive layer contacts the first vertical conductive layer may be defined in the insulating layer, and the third contact hole may be spaced apart from the emission area.

The first horizontal conductive layer, the second horizontal conductive layer, the first vertical conductive layer, and the second vertical conductive layer may form a mesh structure.

A constant voltage may be applied to the mesh structure.

The emission area may include a first sub-emission area and a second sub-emission area, and the second contact hole may be disposed between the first sub-emission area and the second sub-emission area.

Each of the emission area and the pixel electrode may be provided in plurality, and each of pixel groups including two or more emission areas may be spaced apart from each other in the second direction.

Emission areas, which belong to a same pixel group and are adjacent to each other, may be spaced apart from each other by a first distance, emission areas, which belong to different pixel groups and are adjacent to each other, may be spaced apart from each other by a second distance, and the first distance may be less than the second distance.

The pixel electrode may be provided in plurality, and a plurality of pixel electrodes may be arranged in a zigzag manner in the first direction.

According to one or more embodiments, a display apparatus may include a first pixel electrode in which a first emission area is defined, a second pixel electrode spaced apart from the first pixel electrode in a first direction and in which a second emission area is defined, a first horizontal conductive layer extending in the first direction and intersecting the first emission area and the second emission area, a first vertical conductive layer extending in a second direction intersecting the first direction, overlapping the first emission area, and intersecting the first horizontal conductive layer, a second vertical conductive layer extending in the second direction, overlapping the second emission area, and intersecting the first horizontal conductive layer, and an insulating layer disposed between the first horizontal conductive layer and the first vertical conductive layer and between the first horizontal conductive layer and the second vertical conductive layer. A first contact hole through which the first vertical conductive layer contacts the first horizontal conductive layer is defined in the insulating layer, and the first contact hole is disposed at a center portion of the first emission area.

An area where the first horizontal conductive layer and the second vertical conductive layer intersect each other may be spaced apart from a center portion of the second emission area. In the area where the first horizontal conductive layer and the second vertical conductive layer intersect each other, the insulating layer may cover the first horizontal conductive layer.

The display apparatus may further include a third pixel electrode spaced apart from the first pixel electrode in the second direction and in which a third emission area is defined, and a second horizontal conductive layer extending in the first direction, overlapping the third emission area, and intersecting the first vertical conductive layer.

An area where the second horizontal conductive layer and the first vertical conductive layer intersect each other may be spaced apart from a center portion of the third emission area. In the area where the second horizontal conductive layer and the first vertical conductive layer intersect each other, the insulating layer may cover the second horizontal conductive layer.

The display apparatus may further include a fourth pixel electrode spaced apart from the second pixel electrode in the second direction and in which a fourth emission area overlapping the second horizontal conductive layer is defined. A second contact hole through which the second vertical conductive layer contacts the second horizontal conductive layer may be defined in the insulating layer, and the second contact hole may be disposed at a center portion of the fourth emission area.

The first pixel electrode and the third pixel electrode may be spaced apart from each other by a first distance in the second direction, the second pixel electrode and the fourth pixel electrode may be spaced apart from each other by a second distance in the second direction, and the first distance and the second distance may be different from each other.

The first pixel electrode and the second pixel electrode may be arranged in a zigzag manner in the first direction.

The first horizontal conductive layer, the second horizontal conductive layer, the first vertical conductive layer, and the second vertical conductive layer may form a mesh structure.

A constant voltage may be applied to the mesh structure.

These and/or other aspects will become apparent and more readily appreciated from the following description of the embodiments, taken in conjunction with the accompanying drawings.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a schematic plan view of a display panel of a display apparatus according to an embodiment;

FIG. 2 is a schematic diagram of an equivalent circuit of a representative pixel included in a display apparatus according to an embodiment;

FIG. 3 is a schematic layout view illustrating a display apparatus according to an embodiment;

FIG. 4 is a schematic plan view illustrating a relationship between a pixel electrode and a driving voltage line according to an embodiment;

FIG. 5 is a schematic cross-sectional view showing a cross-section taken along line I-I′ of the display apparatus shown in FIG. 4;

FIG. 6 is a schematic cross-sectional view showing a cross-section taken along line II-II′ of the display apparatus shown in FIG. 4;

FIG. 7 is a schematic diagram showing a relationship between an emission area and a driving voltage line according to an embodiment;

FIG. 8 is a schematic diagram of an equivalent circuit schematically showing a connection relationship between a horizontal driving voltage line and a vertical driving voltage line shown in FIG. 7;

FIG. 9 is a schematic diagram showing a relationship between an emission area and a driving voltage line according to an embodiment;

FIG. 10 is a schematic diagram of an equivalent circuit schematically showing a connection relationship between a horizontal driving voltage line and a vertical driving voltage line shown in FIG. 9;

FIG. 11 is a schematic diagram of an equivalent circuit of a representative pixel included in a display apparatus according to an embodiment;

FIG. 12 is a schematic layout view illustrating a display apparatus according to an embodiment;

FIG. 13 is a schematic layout view illustrating an arrangement of a first conductive layer and a second conductive layer of a display apparatus according to an embodiment;

FIG. 14 is a schematic layout view illustrating a relationship between a pixel electrode and a reference voltage line according to an embodiment;

FIG. 15 is a schematic cross-sectional view showing a cross-section taken along line III-III′ of the display apparatus shown in FIG. 14;

FIG. 16 is a schematic cross-sectional view showing a cross-section taken along line IV-IV′ of the display apparatus shown in FIG. 14; and

FIG. 17 is a schematic diagram of an equivalent circuit schematically showing a connection relationship between a horizontal reference voltage line and a vertical reference voltage line shown in FIG. 14.

### DETAILED DESCRIPTION OF THE EMBODIMENTS

Reference will now be made in detail to embodiments, examples of which are illustrated in the accompanying drawings, wherein like reference numerals refer to like elements throughout. In this regard, the embodiments may have different forms and should not be construed as being limited to the descriptions set forth herein. Accordingly, the embodiments are merely described below, by referring to the figures, to explain aspects of the description. As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof.

As the disclosure allows for various changes and numerous embodiments, embodiments will be illustrated in the drawings and described in detail in the written description. Hereinafter, effects and features of the disclosure and a method for accomplishing them will be described more fully with reference to the accompanying drawings, in which embodiments of the disclosure are shown. The disclosure may, however, be embodied in many different forms and should not be construed as limited to the embodiments set forth herein.

One or more embodiments will be described below in more detail with reference to the accompanying drawings. Those components that are the same as or are in correspondence with each other are rendered the same reference numeral regardless of the figure number, and redundant explanations are omitted.

It will be understood that although the terms “first,” “second,” etc. may be used herein to describe various components, these components should not be limited by these terms. These components are only used to distinguish one component from another.

As used herein, the singular forms “a,” “an,” and “the” are intended to include the plural forms as well, unless the context clearly indicates otherwise.

The terms “comprises” and/or “comprising” used herein specify the presence of stated features or components, but do not preclude the presence or addition of one or more other features or components.

When a layer, region, or component is referred to as being “formed on” another layer, region, or component, it can be directly or indirectly formed on the other layer, region, or component. For example, intervening layers, regions, or components may be present.

When a layer, region, or component is referred to as being “connected” or “coupled” to another layer, region, or component, it can be directly connected or coupled to the other layer, region, or/and component or intervening layers, regions, or components may be present. For example, when a layer, region, or component is referred to as being “electrically connected” or “electrically coupled” to another layer, region, or component, it can be directly electrically connected or coupled to the other layer, region, and/or component or intervening layers, regions, or components may be present.

In the description, “A and/or B” represents A or B, or A and B. The expression “at least one of A and B” indicates only A, only B, both A and B, or variations thereof.

In the following examples, the x-axis, the y-axis and the z-axis are not limited to three axes of the rectangular coordinate system, and may be interpreted in a broader sense. For example, the x-axis, the y-axis, and the z-axis may be perpendicular to one another, or may represent different directions that are not perpendicular to one another.

In the following embodiments, when referred to “planar,” it means when an object is viewed from above, and when referred to “sectional,” it means when a cross section formed by vertically cutting an object is viewed from the side. In the following embodiments, a first component “overlapping” a second component refers to the first component being positioned above or below the second component.

Sizes of elements in the drawings may be exaggerated or reduced for convenience of explanation. For example, since sizes and thicknesses of components in the drawings are arbitrarily illustrated for convenience of explanation, embodiments are not limited thereto.

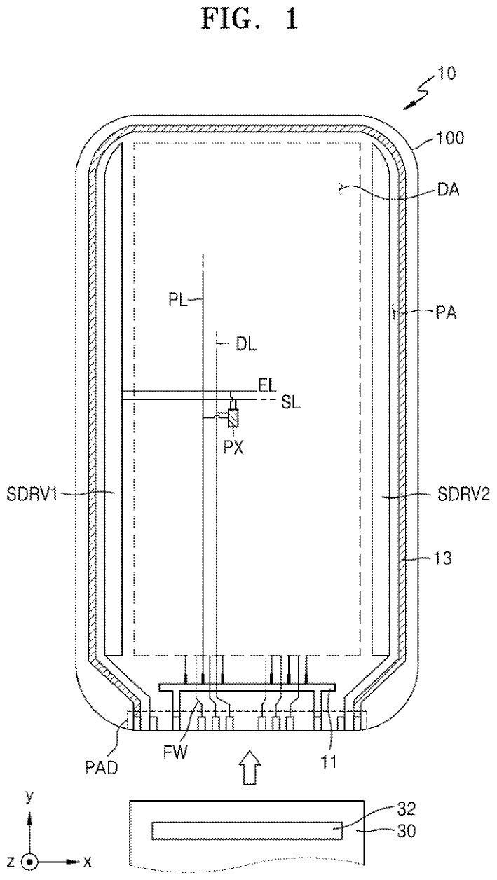

FIG. 1 is a schematic plan view of a display panel 10 of a display apparatus according to an embodiment.

The display apparatus according to an embodiment may include the display panel 10. The display panel 10 may include a display area DA and a peripheral area PA. Various components of the display panel 10 may be arranged on a substrate 100. For example, the substrate 100 may include the display area DA and the peripheral area PA.

In a plan view, the display area DA may have a rectangular shape as shown in FIG. 1. According to another embodiment, the display area DA may have other polygonal shape (e.g., a triangular shape, a pentagonal shape, or a hexagonal shape), a circular shape, an elliptical shape, an irregular shape, or the like. The display area DA may have a shape with rounded corners. The peripheral area PA may be a non-display area in which no display elements are arranged. The display area DA may be surrounded (e.g., entirely surrounded) by the peripheral area PA.

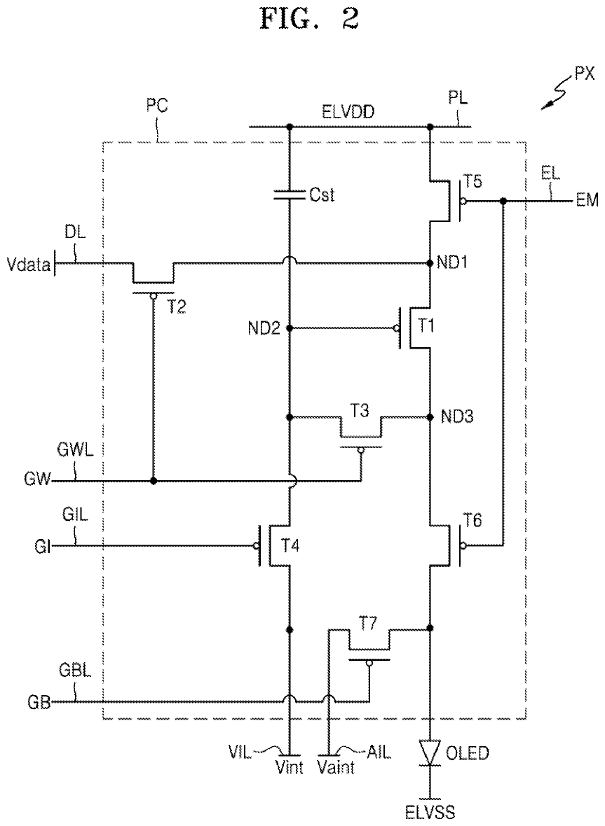

Pixels PX including various display elements, such as an organic light-emitting diode OLED (see FIG. 2), may be arranged in the display area DA. Pixels PX may be included, and the pixels PX may be arranged in any of various patterns, such as a stripe pattern, a PenTile™ pattern, or a mosaic pattern, in an x-axis direction and a y-axis direction, thereby displaying an image. Each of the pixels PX may emit, for example, red light, green light, blue light, or white light.

Pixel circuits, which drive the pixels PX, may be electrically connected to outer circuits arranged in the peripheral area PA, respectively. A first scan driving circuit SDRV1, a second scan driving circuit SDRV2, a terminal unit PAD, a driving voltage supply line 11, and a common voltage supply line 13 may be arranged in the peripheral area PA.

The first scan driving circuit SDRV1 may apply a scan signal, via a scan line SL, to each of the pixel circuits that drive the pixels PX. The first scan driving circuit SDRV1 may apply an emission control signal to each of the pixel circuits via an emission control line EL. The second scan driving circuit SDRV2 may be positioned on a side of the display area DA that is opposite to the side where the first scan driving circuit SDRV1 is positioned, and may be approximately parallel to the first scan driving circuit SDRV1. Some of the pixel circuits of the pixels PX arranged in the display area DA may be electrically connected to the first scan driving circuit SDRV1, and the remaining pixel circuits may be electrically connected to the second scan driving circuit SDRV2. In another example, the second scan driving circuit SDRV2 may not be included.

The terminal unit PAD may be on a side of the substrate 100. The terminal unit PAD may be exposed without being covered by an insulating layer, and may be connected to a display circuit board 30. A display driving unit 32 may be disposed on the display circuit board 30.

The display driving unit 32 may generate a control signal that is transmitted to the first scan driving circuit SDRV1 and the second scan driving circuit SDRV2. The display driving unit 32 may generate a data signal, and the generated data signal may be transmitted to the pixel circuits of the pixels PX via fanout wirings FW and data lines DL connected to the fanout wirings FW.

The display driving unit 32 may supply a driving voltage ELVDD (see FIG. 2) to the driving voltage supply line 11, and may supply a common voltage ELVSS (see FIG. 2) to the common voltage supply line 13. The driving voltage ELVDD may be applied to the pixel circuits of the pixels PX via a driving voltage line PL connected to the driving voltage supply line 11, and the common voltage ELVSS may be applied to an opposite electrode of each display element via the common voltage supply line 13.

The driving voltage supply line 11 may be connected to the terminal unit PAD, and may extend on a lower side of the display area DA in the x-axis direction. The common voltage supply line 13 may be connected to the terminal unit PAD, and may have a loop shape of which a side is open, and thus may surround a portion of the display area DA.

The display apparatus may further include a cover window. The cover window may be disposed on the display panel 10. The cover window may function to protect the display panel 10. According to an embodiment, the cover window may be a flexible window. The cover window may include glass, sapphire or plastic. For example, the cover window may be ultra-thin glass or colorless polyimide. The cover window may be attached to the display panel 10 by a transparent adhesion member such as an optically clear adhesive (OCA) film.

The display apparatus according to an embodiment may be implemented as an electronic apparatus such as a smartphone, a mobile phone, a smart watch, a navigation device, a game player, a TV, a vehicle head unit, a notebook computer, a laptop computer, a tablet computer, a personal media player (PMP), or a personal digital assistant (PDA). The electronic apparatus may be flexible.

FIG. 2 is a schematic diagram of an equivalent circuit of a representative pixel PX included in the display apparatus according to an embodiment.

Referring to FIG. 2, the pixel PX may include a pixel circuit PC and an organic light-emitting diode OLED electrically connected to the pixel circuit PC.

The pixel circuit PC may include a first transistor T1, which is a driving transistor, and second, third, fourth, fifth, sixth, and seventh transistors T2, T3, T4, T5, T6, and T7, which are switching transistors. According to the type (e.g., P-type or N-type) of transistor and/or operating conditions thereof, a first terminal of each of the first through seventh transistors T1 T2, T3, T4, T5, T6, and T7 may be a source terminal or a drain terminal, and a second terminal thereof may be a different terminal than the first terminal. For example, in case that the first terminal is a source terminal, the second terminal may be a drain terminal. According to an embodiment, the source terminal and the drain terminal may be interchangeably referred to as a source electrode and a drain electrode, respectively.

The pixel circuit PC may be connected to a first scan line GWL that transmits a first scan signal GW, a second scan line GIL that transmits a second scan signal GI, a third scan line GBL that transmits a third scan signal GB, an emission control line EL that transmits an emission control signal EM, a data line DL that transmits a data signal Vdata, a driving voltage line PL that transmits a driving voltage ELVDD, a first initializing voltage line VIL that transmits a first initializing voltage Vint, and a second initializing voltage line AIL that transmits a second initializing voltage Vaint.

The first transistor T1 may be connected between the driving voltage line PL and the organic light-emitting diode OLED. The first transistor T1 may be connected to the driving voltage line PL through the fifth transistor T5, and may be electrically connected to the organic light-emitting diode OLED through the sixth transistor T6. The first transistor T1 may include a gate terminal connected to a second node ND2, a first terminal connected to a first node ND1, and a second terminal connected to a third node ND3. The first transistor T1 may receive a data signal according to a switching operation of the second transistor T2 and may supply a driving current to the organic light-emitting diode OLED.

The second transistor T2 (e.g., data write transistor) may be connected between the data line DL and the first node ND1. The first node ND1 may be a node where the first transistor T1 and the fifth transistor T5 are connected. The second transistor T2 may include a gate terminal connected to the first scan line GWL, a first terminal connected to the data line DL, and a second terminal connected to the first node ND1 (or to the first terminal of the first transistor T1). The second transistor T2 may be turned on in response to the first scan signal GW received through the first scan line GWL, to perform a switching operation of transmitting the data signal Vdata received through the data line DL to the first node ND1.

The third transistor T3 (e.g., compensation transistor) may be connected between the second node ND2 and the third node ND3. The second node ND2 may be a node connected to the gate terminal of the first transistor T1, and the third node ND3 may be a node connected to the first transistor T1 and the sixth transistor T6. The third transistor T3 may include a gate terminal connected to the first scan line GWL, a first terminal connected to the second node ND2 (or to the gate terminal of the first transistor T1), and a second terminal connected to the third node ND3 (or to the second terminal of the first transistor T1). The third transistor T3 may be turned on in response to the first scan signal GW received through the first scan line GWL to diode-connect the first transistor T1, thereby compensating for a threshold voltage of the first transistor T1.

The fourth transistor T4 (e.g., first initialization transistor) may be connected between the second node ND2 and the first initializing voltage line VIL. The fourth transistor T4 may include a gate connected to the second scan line GIL, a first terminal connected to the second node ND2, and a second terminal connected to the first initializing voltage line VIL. The fourth transistor T4 may be turned on in response to the second scan signal GI received through the second scan line GIL, to transmit the first initializing voltage Vint to the gate terminal of the first transistor T1 thereby initializing the gate voltage of the first transistor T1.

The fifth transistor T5 (e.g., first emission control transistor) may be connected between the driving voltage line PL and the first node ND1. The sixth transistor T6 (e.g., second emission control transistor) may be connected between the third node ND3 and the organic light-emitting diode OLED. The fifth transistor T5 may include a gate terminal connected to the emission control line EL, a first terminal connected to the driving voltage line PL, and a second terminal connected to the first node ND1.

The sixth transistor T6 may include a gate terminal connected to the emission control line EL, a first terminal connected to the third node ND3, and a second terminal connected to a pixel electrode of the organic light-emitting diode OLED. The fifth transistor T5 and the sixth transistor T6 may be simultaneously turned on according to the emission control signal EM received via the emission control line EL, and thus the driving current may be able to flow in the organic light-emitting diode OLED.

The seventh transistor T7 (e.g., second initialization transistor) may be connected between the organic light-emitting diode OLED and the second initializing voltage line AIL. The seventh transistor T7 may include a gate terminal connected to the third scan line GBL, a first terminal connected to the second terminal of the sixth transistor T6 and the pixel electrode of the organic light-emitting diode OLED, and a second terminal connected to the second initializing voltage line AIL. The seventh transistor T7 may be turned on in response to the third scan signal GB received via the third scan line GBL to transmit the second initializing voltage Vaint to the pixel electrode of the organic light-emitting diode OLED and initialize a voltage of the pixel electrode of the organic light-emitting diode OLED. The second initializing voltage Vaint supplied by the second initializing voltage line AIL may be different from the first initializing voltage Vint supplied by the first initializing voltage line VIL. According to an embodiment, different second initializing voltages Vaint may be supplied to different pixels PX according to the colors in which the pixels PX emit light. According to an embodiment, the seventh transistor T7 may be omitted.

The driving voltage ELVDD, the common voltage ELVSS, the first initializing voltage Vint, and the second initializing voltage Vaint may be constant voltages without voltage change during one frame. The driving voltage line PL, the first initializing voltage line VIL, and the second initializing voltage line AIL may be constant voltage lines for transmitting constant voltages. These constant voltage lines may be formed in a mesh structure to reduce differences in light emission characteristics of pixels due to a voltage drop across the display area DA (see FIG. 1).

A storage capacitor Cst may include a first electrode connected to the second node ND2 and a second electrode connected to the driving voltage line PL. The storage capacitor Cst may maintain a voltage applied to the gate electrode of the first transistor T1, by storing and maintaining a voltage corresponding to a difference between voltages respectively supplied to end portions (e.g., opposite end portions) of the first electrode and the second electrode.

The organic light-emitting diode OLED may include the pixel electrode (e.g., an anode) and an opposite electrode (e.g., a cathode) facing the pixel electrode, and the opposite electrode may receive the common voltage ELVSS. The organic light-emitting diode OLED may display an image by receiving a driving current corresponding to a voltage value stored in the storage capacitor Cst from the first transistor T1 and emitting light in a certain color.

In FIG. 2, the transistors of a pixel circuit PC may be P-type transistors. However, embodiments are not limited thereto. For example, the transistors of the pixel circuit PC may be N-type transistors, or some of the transistors of the pixel circuit PC may be P-type transistors and the others may be N-type transistors.

In FIG. 2, each of the third transistor T3 and the fourth transistor T4 may include one gate terminal. According to another embodiment, each of the third transistor T3 and the fourth transistor T4 may include two gate terminals.

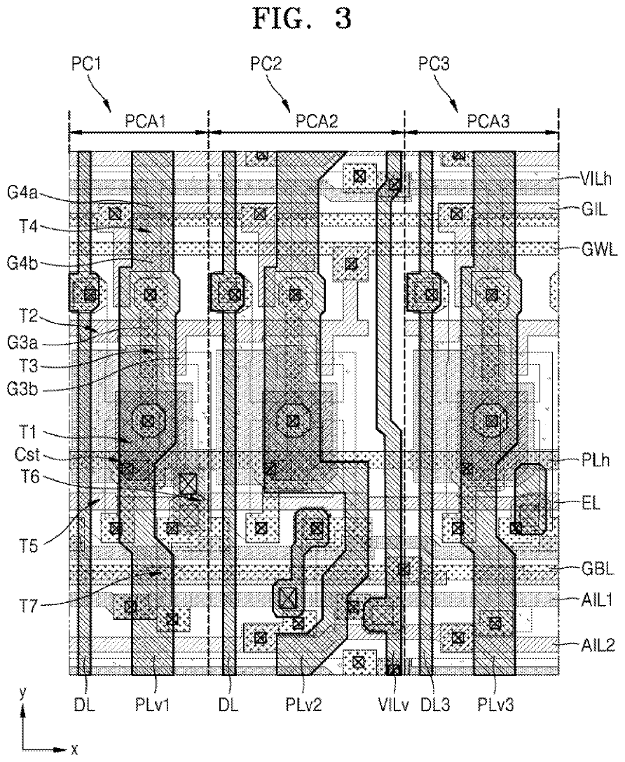

FIG. 3 is a schematic layout view illustrating a display apparatus according to an embodiment. FIG. 3 may correspond to a layout view of the pixel PX shown in FIG. 2. Hereinafter, because first, second, and third pixel circuits PC1, PC2, and PC3 have identical devices disposed in similar positions, they will not be described separately for descriptive convenience.

Pixels PX (see FIG. 1) arranged in the display area DA (see FIG. 1) may be repeatedly arranged to form rows and columns in a certain pattern in x-axis and y-axis directions. Each of the pixels PX may include a pixel circuit and an organic light-emitting diode OLED (see FIG. 2) electrically connected to the pixel circuit. A pixel electrode of each of the organic light-emitting diodes OLED may be disposed over the pixel circuit. A pixel electrode may be disposed over (e.g., directly over) a pixel circuit corresponding thereto to overlap the pixel circuit, or may be disposed offset to overlap a portion of a pixel circuit of another pixel disposed in a column or row adjacent to the pixel circuit.

Referring to FIG. 3, a first pixel area PCA1, a second pixel area PCA2, and a third pixel area PCA3 may be repeatedly arranged in the x-axis direction to form a row. For example, the first pixel circuit PC1 may be disposed in the first pixel area PCA1, the second pixel circuit PC2 may be disposed in the second pixel area PCA2, and the third pixel circuit PC3 may be disposed in the third pixel area PCA3. The first pixel circuit PC1 may be electrically connected to a first organic light-emitting diode that emits light in a first color, the second pixel circuit PC2 may be electrically connected to a second organic light-emitting diode that emits light in a second color, and the third pixel circuit PC3 may be electrically connected to a third organic light-emitting diode that emits light in a third color.

The first through seventh transistors T1, T2, T3, T4, T5, T6, and T7 may be disposed in each of the first pixel area PCA1, the second pixel area PCA2, and the third pixel area PCA3. A semiconductor layer of each of the first through seventh transistors T1, T2, T3, T4, T5, T6, and T7 may include a channel region and a source region and a drain region on sides (e.g., opposite sides) of the channel region. The channel region of the first transistor T1 may be formed to be long by being curved, so that the driving range of the gate voltage applied to the gate electrode may be expanded. In some cases, a source region or a drain region may be interpreted as a source electrode or drain electrode of a transistor. For example, a source electrode and a drain electrode of the first transistor T1 may correspond to a source region and a drain region doped with impurities near the channel region, respectively.

The first scan line GWL, the second scan line GIL, the third scan line GBL, a first horizontal initializing voltage line VILh, a horizontal driving voltage line PLh, a (2-1)th initializing voltage line AIL1, and a (2-2)th initializing voltage line AIL2 may each extend in the first direction (e.g., x-axis direction) and may be arranged over the first pixel area PCA1, the second pixel area PCA2, and the third pixel area PCA3.

The first scan line GWL, the second scan line GIL, and the third scan line GBL may each include upper wiring (or upper conductive layer) and lower wiring (or lower conductive layer) arranged on different layers. The upper wiring and the lower wiring may overlap each other, and one or more insulating layers may be disposed on the upper wiring and the lower wiring. The upper wiring and the lower wiring may be electrically connected to each other through a contact hole defined in the one or more insulating layers.

The gate electrode of the second transistor T2 may be a portion of the first scan line GWL that intersects (or overlaps) the semiconductor layer. The gate electrode of the third transistor T3 may be portions G3a of the first scan line GWL intersecting the semiconductor layer, or may be portions G3b protruding from the first scan line GWL. The third transistor T3 may be implemented as two transistors connected to each other in series.

The gate electrode of the fourth transistor T4 may be portions G4a of the second scan line GIL intersecting the semiconductor layer, or may be portions G4b protruding from the second scan line GIL. The fourth transistor T4 may be implemented as two transistors connected to each other in series.

The gate electrode of the fifth transistor T5 and the gate electrode of the sixth transistor T6 may be portions of the emission control line EL intersecting the semiconductor layer. The gate electrode of the seventh transistor T7 may be portions of the third scan line GBL.

The gate electrode of the first transistor T1 may be formed in an island type. The second electrode of the storage capacitor Cst may overlap the gate electrode of the first transistor T1. For example, the gate electrode of the first transistor T1 may be formed integrally with the first electrode of the storage capacitor Cst (see FIG. 2).

Each of the first horizontal initializing voltage line VILh, the horizontal driving voltage line PLh, the (2-1)th initializing voltage line AIL1, and the (2-2)th initializing voltage line AIL2 may be a constant voltage line that transmits a constant voltage. The first horizontal initializing voltage line VILh and the horizontal driving voltage line PLh may be horizontal wirings (or horizontal conductive layers) that are electrically connected to their corresponding vertical wirings (or vertical conductive layers) to form a mesh structure.

The first horizontal initializing voltage line VILh may overlap a portion of the semiconductor layer extending in the first direction (e.g., x-axis direction). The portion of the semiconductor layer overlapping the first horizontal initializing voltage line VILh may be electrically connected to the first horizontal initializing voltage line VILh. The first horizontal initializing voltage line VILh may be a portion of the first initializing voltage line VIL (see FIG. 2) that is electrically connected to the second terminal of the fourth transistor T4.

For example, the first horizontal initializing voltage line VILh may be electrically connected to a first vertical initializing voltage line VILv extending in the second direction (e.g., y-axis direction) thereby forming a mesh structure. The first vertical initializing voltage line VILv may be disposed in the second pixel area PCA2, and may be disposed on a different layer from a layer on which the first horizontal initializing voltage line VILh is disposed. For example, one or more insulating layers may be disposed between the first horizontal initializing voltage line VILh and the first vertical initializing voltage line VILv, and the first horizontal initializing voltage line VILh and the first vertical initializing voltage line VILv may contact (or may electrically contact) each other through a contact hole defined in the one or more insulating layers.

The horizontal driving voltage line PLh may overlap a portion of the storage capacitor Cst. The horizontal driving voltage line PLh may be electrically connected to the second electrode of the storage capacitor Cst. The horizontal driving voltage line PLh may include a protruding portion, and the protruding portion of the horizontal driving voltage line PLh may be electrically connected to the first terminal of the fifth transistor T5. The horizontal driving voltage line PLh may be a portion of the driving voltage line PL (see FIG. 2).

For example, the horizontal driving voltage line PLh may be electrically connected to a first vertical driving voltage line PLv1, a second vertical driving voltage line PLv2, and a third vertical driving voltage line PLv3 each extending in the second direction (e.g., y-axis direction) thereby forming a mesh structure. The first vertical driving voltage line PLv1 may be disposed in the first pixel area PCA1, the second vertical driving voltage line PLv2 may be disposed in the second pixel area PCA2, and the third vertical driving voltage line PLv3 may be disposed in the third pixel area PCA3.

The first vertical driving voltage line PLv1, the second vertical driving voltage line PLv2, and the third vertical driving voltage line PLv3 may be disposed on a different layer from a layer on which the horizontal driving voltage line PLh is disposed. For example, at least one insulating layer may be disposed between the first vertical driving voltage line PLv1, the second vertical driving voltage line PLv2, the third vertical driving voltage line PLv3, and the horizontal driving voltage line PLh, and the first vertical drive voltage line PLv1, the second vertical drive voltage line PLv2, the third vertical drive voltage line PLv3 may contact the horizontal driving voltage line PLh through a contact hole defined in the one or more insulating layers.

The (2-1)th initializing voltage line AIL1 may correspond to the second initializing voltage line AIL (see FIG. 2). The (2-1)th initializing voltage line AIL1 may be connected to the second terminal of the seventh transistor T7 of the first pixel circuit PC1.

The (2-2)th initializing voltage line AIL2 may correspond to the second initializing voltage line AIL (see FIG. 2). The (2-2)th initializing voltage line AIL2 may be connected to the second terminal of the seventh transistor T7 of the second pixel circuit PC2 and the second terminal of the seventh transistor T7 of the third pixel circuit PC3.

The (2-1)th initializing voltage line AIL1 and the (2-2)th initializing voltage line AIL2 may be arranged on different layers. A second initializing voltage, which the (2-1)th initializing voltage line AIL1 transmits to the first pixel circuit PC1, a second initializing voltage, which the (2-2)th initializing voltage line AIL2 transmits to the second pixel circuit PC2 and the third pixel circuit PC3, may be different from each other.

For example, the display apparatus may further include a vertical voltage line extending in the second direction (e.g., y-axis direction) and electrically connected to the (2-1)th initializing voltage line AIL1. The (2-1)th initializing voltage line AIL1 and the vertical voltage line may be arranged on different layers and may form a mesh structure.

Likewise, the display apparatus may further include a vertical voltage line extending in the second direction (e.g., y-axis direction) and electrically connected to the (2-2)th initializing voltage line AIL2. The (2-2)th initializing voltage line AIL2 and the vertical voltage line may be arranged on different layers and may form a mesh structure.

The data line DL may extend in the second direction (e.g., y-axis direction) and may be electrically connected to the first terminal of the second transistor T2. The data line DL, the first vertical driving voltage line PLv1, the second vertical driving voltage line PLv2, and the third vertical driving voltage line PLv3 may be disposed on the same layer.

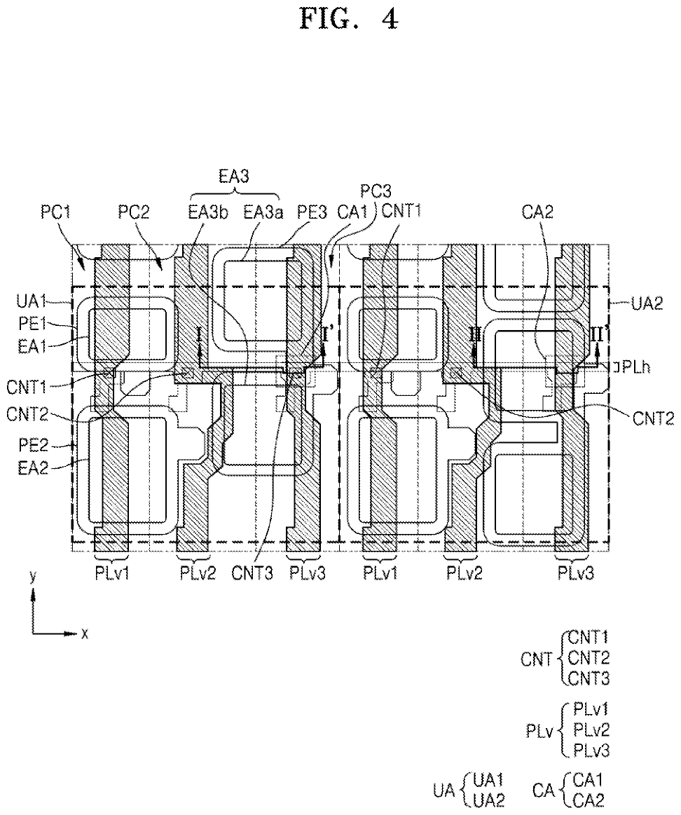

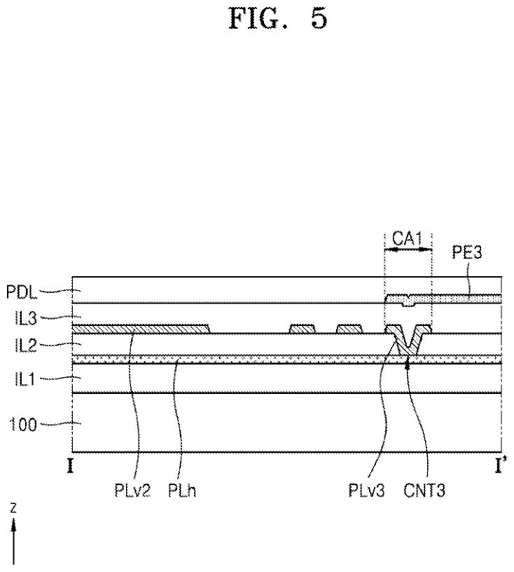

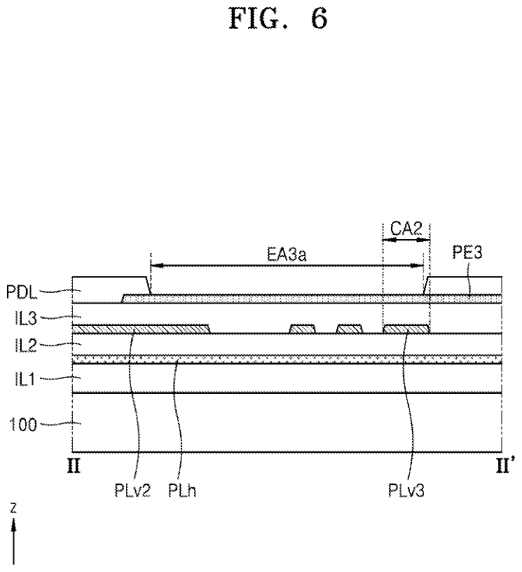

FIG. 4 is a schematic plan view illustrating a relationship between a pixel electrode and a driving voltage line according to an embodiment. FIG. 5 is a schematic cross-sectional view showing a cross-section taken along line I-I′ of the display apparatus shown in FIG. 4, and FIG. 6 is a schematic cross-sectional view showing a cross-section taken along line II-II′ of the display apparatus shown in FIG. 4.

Referring to FIGS. 4, 5, and 6, a first insulating layer IL1 having a multi-layer structure may be disposed on the substrate 100. For example, circuit elements forming the first, second, and third pixel circuits PC1, PC2, and PC3 may be disposed between insulating layers included in the first insulating layer IL1.

The horizontal driving voltage line PLh extending in the first direction (e.g., x-axis direction) may be disposed over the first insulating layer IL1, and a second insulating layer IL2 may be disposed over the first insulating layer IL1 to cover the horizontal driving voltage line PLh.

The vertical driving voltage line PLv extending in the second direction (e.g., y-axis direction) may be disposed over the second insulating layer IL2. The vertical driving voltage line PLv may include a first vertical driving voltage line PLv1, a second vertical driving voltage line PLv2, and a third vertical driving voltage line PLv3. A third insulating layer IL3 may be disposed over the second insulating layer IL2 to cover the vertical driving voltage line PLv.

First, second, and third pixel electrodes PE1, PE2, and PE3 may be disposed over the third insulating layer IL3. The first pixel electrode PE1 may be electrically connected to the first pixel circuit PC1, the second pixel electrode PE2 may be electrically connected to the second pixel circuit PC2, and the third pixel electrode PE3 may be electrically connected to the third pixel circuit PC3.

The first insulating layer IL1 may include an inorganic insulating material and/or an organic insulating material. Each of the second insulating layer IL2 and the third insulating layer IL3 may include an organic insulating material. The inorganic insulating material may include silicon oxide, silicon nitride, or silicon oxynitride. The organic insulating material may include a commercial polymer such as polystyrene (PS), benzocyclobutene (BCB), hexamethyldisiloxane (HMDSO), polymethyl methacrylate (PMMA) or polystyrene (PS), a polymer derivative having a phenol-based group, an acrylic-based polymer, an imide-based polymer such as polyimide, an aryl ether-based polymer, an amide-based polymer, a fluorine-based polymer, a p-xylene-based polymer, a vinyl alcohol-based polymer, or the like.

A pixel definition layer PDL may be disposed over the third insulating layer IL3 to cover the first, second, and third pixel electrodes PE1, PE2, and PE3. First, second, and third emission areas EA1, EA2, and EA3 may be defined by openings defined in the pixel definition layer PDL. In the first, second, and third emission areas EA1, EA2, and EA3, emission layers of organic light-emitting diodes respectively connected to the first, second, and third pixel circuits PC1, PC2, and PC3 may be disposed. The pixel definition layer PDL may include an organic insulating material, such as polyimide, polyamide, acryl resin, benzocyclobutene, hexamethyldisiloxane (HMDSO), or phenol resin.

Each of the first, second, and third emission areas EA1, EA2, and EA3 may correspond to (or overlap) respective portions of the first, second, and third pixel electrodes PE1, PE2, and PE3, respectively. The third emission area EA3 may include a first sub-emission area EA3a and a second sub-emission area EA3b that are spaced apart from each other. The third pixel electrode PE3 may include two sub-electrodes connected to the same third pixel circuit PC3, and the first sub-emission area EA3a and the second sub-emission area EA3b may correspond to respective portions of the two sub-electrodes.

In a plan view, each of the first, second, and third emission areas EA1, EA2, and EA3 may have a shape such as a polygon (e.g., a rectangle or an octagon), a circle, or an oval. Examples of the polygon may also include a shape of which corners (e.g., vertexes) are rounded.

The first emission area EA1, the second emission area EA2, and the third emission area EA3 may have different areas. For example, the second emission area EA2 may have a larger area than the first emission area EA1. The area of each of the first sub-emission area EA3a and the second sub-emission area EA3b may be less than that of the second emission area EA2, but a sum of the respective areas of the first sub-emission area EA3a and the second sub-emission area EA3b may be greater than the area of the second emission area EA2. Embodiments are not limited to thereto, and the shape and area of each of the first emission area EA1, the second emission area EA2, and the third emission area EA3 may be formed in various ways.

The first emission area EA1, the second emission area EA2, and the third emission area EA3 may be disposed in one unit area UA. The first emission area EA1 and the second emission area EA2 may be positioned within a unit area UA. The third emission area EA3 may be positioned within one unit area UA, or may be disposed within neighboring unit areas UA. Unit areas UA may be provided and repeatedly arranged to form a matrix in the first direction (e.g., x-axis direction) and the second direction (e.g., y-axis direction).

In one unit area UA, the first emission area EA1 and the second emission area EA2 may be spaced apart from each other in the second direction (e.g., y-axis direction). The third emission area EA3 may be spaced apart from the first emission area EA1 and the second emission area EA2 in the first direction (e.g., x-axis direction). In case that the third emission area EA3 includes the first sub-emission area EA3a and the second sub-emission area EA3b, the first sub-emission area EA3a and the second sub-emission area EA3b may be spaced apart from each other in the second direction (e.g., y-axis direction).

In each unit area UA, respective locations (or positions) of the first emission area EA1 and the second emission area EA2 may be fixed, but a location (or position) of the third emission area EA3 may change. For example, the third emission areas EA3 may be arranged in a zigzag manner in the first direction (e.g., x-axis direction). For example, the first sub-emission areas EA3a and the second sub-emission areas EA3b may be arranged in a zigzag manner in the first direction (e.g., x-axis direction).

In one unit area UA, vertical driving voltage lines PLv each extending in the second direction (e.g., y-axis direction) may be formed. For example, within a unit area UA, the first vertical driving voltage line PLv1, the second vertical driving voltage line PLv2, and the third vertical driving voltage line PLv3 may be spaced apart from each other in the first direction (e.g., x-axis direction). Unit areas UA forming a column in the second direction (e.g., y-axis direction) may share the same vertical driving voltage lines PLv. In each unit area UA, a horizontal driving voltage line PLh extending in the first direction (e.g., x-axis direction) may be formed. Unit areas UA forming a row in the first direction (e.g., x-axis direction) may share the same horizontal driving voltage lines PLh.

Contact holes CNT for forming a mesh structure by electrically connecting the horizontal driving voltage line PLh to the vertical driving voltage line PLv may not overlap the first, second, and third emission areas EA1, EA2, and EA3. For example, the contact holes CNT may be spaced apart from the first, second, and third emission areas EA1, EA2, and EA3.

For example, the horizontal driving voltage line PLh and the first vertical driving voltage line PLv1 may contact (or may electrically contact) each other through a first contact hole CNT1 defined in the second insulating layer IL2. The first contact hole CNT1 may not overlap the first, second, and third emission areas EA1, EA2, and EA3.

The horizontal driving voltage line PLh and the second vertical driving voltage line PLv2 may contact (or may electrically contact) each other through a second contact hole CNT2 defined in the second insulating layer IL2. The second contact hole CNT2 may not overlap the first, second, and third emission areas EA1, EA2, and EA3.

The horizontal driving voltage line PLh may extend in the first direction (e.g., x-axis direction) between the first emission area EA1 and the second emission area EA2. An area where the horizontal drive voltage line PLh and the first vertical drive voltage line PLv1 intersect each other, and an area where the horizontal drive voltage line PLh and the second vertical drive voltage line PLv2 intersect each other, may not overlap the first emission area EA1, the second emission area EA2, and the third emission area EA3 in all unit areas UA.

However, because the third emission areas EA3 are arranged in a zigzag manner in the first direction (e.g., x-axis direction), an area where the horizontal driving voltage line PLh and the third vertical driving voltage line PLv3 intersect each other may not overlap the first sub-emission area EA3a and the second sub-emission area EA3b in some unit areas, but an area where the horizontal driving voltage line PLh and the third vertical driving voltage line PLv3 intersect each other may overlap the first sub-emission area EA3a or the second sub-emission area EA3b in the remaining unit areas. For example, intersection areas CA may include a first intersection area CA1 and a second intersection area CA2.

For example, in the first unit area UA1, the first intersection area CA1 where the horizontal driving voltage line PLh and the third vertical driving voltage line PLv3 intersect each other may be disposed between the first sub-emission area EA3a and the second sub-emission area EA3b. For example, because the first intersection area CA1 does not overlap the first, second, and third emission areas EA1, EA2, and EA3, a third contact hole CNT3 via which the horizontal drive voltage line PLh contacts (or electrically contacts) the third vertical driving voltage line PLv3 may be positioned in the first intersection area CA1. The third contact hole CNT3 may be defined in the second insulating layer IL2.

However, in the second unit area UA2, the second intersection area CA2 where the horizontal driving voltage line PLh and the third vertical driving voltage line PLv3 intersect each other may overlap the first sub-emission area EA3a. The second intersection area CA2 may be spaced apart from a center portion of the first sub-emission area EA3a. In the description, the center portion of an area means that the area is vertically and horizontally symmetrical with respect to the center portion. For example, a certain area may be vertically symmetrical about an imaginary line that passes through its center portion and extends in the first direction (e.g., x-axis direction), and may be horizontally symmetrical about an imaginary line that passes through its center portion and extends in the second direction (e.g., y-axis direction).

In case that a contact hole via which the horizontal driving voltage line PLh contacts (or electrically contacts) the third vertical driving voltage line PLv3 is defined in the second intersection area CA2, the emission characteristics of a pixel according to the viewing angle may vary. Accordingly, the contact hole may not be disposed in the second intersection area CA2. For example, in the second intersection area CA2, the second insulating layer IL2 may cover the horizontal driving voltage line PLh and may separate the horizontal driving voltage line PLh from the third vertical driving voltage line PLv3 in a thickness direction (e.g., z-axis direction).

In case that third emission areas EA3 are repeatedly arranged in a zigzag manner in the first direction (e.g., x-axis direction) in a certain pattern, the third contact hole CNT3 via which the horizontal driving voltage line PLh contacts (or electrically contacts) the third vertical driving voltage line PLv3 may also be repeatedly arranged in a certain pattern. The third contact hole CNT3 may be defined in unit areas UA where the third emission area EA3 does not overlap the area where the horizontal driving voltage line PLh and the third vertical driving voltage line PLv3 intersect each other. However, the third contact hole CNT3 may be omitted in unit areas UA where the third emission area EA3 overlaps the area where the horizontal driving voltage line PLh and the third vertical driving voltage line PLv3 intersect each other.

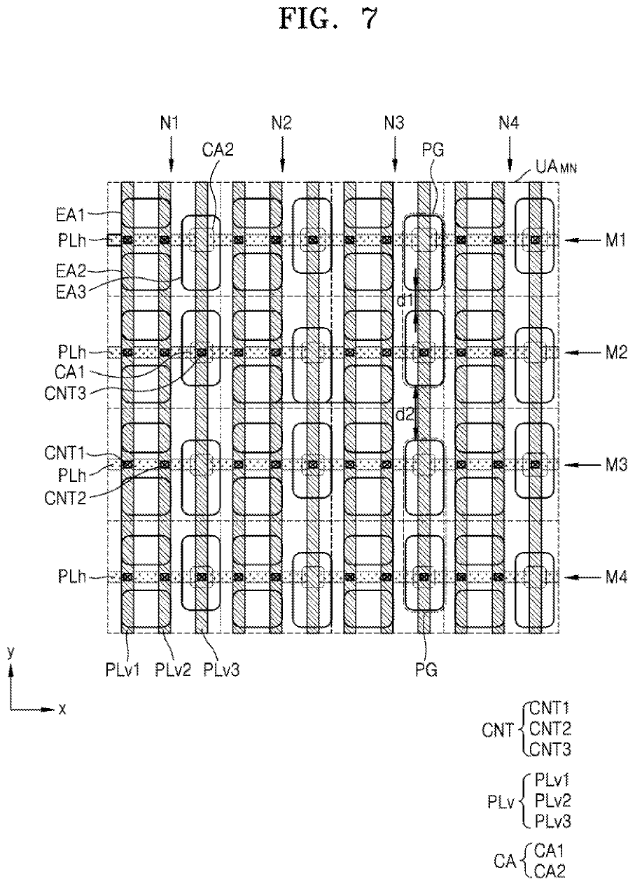

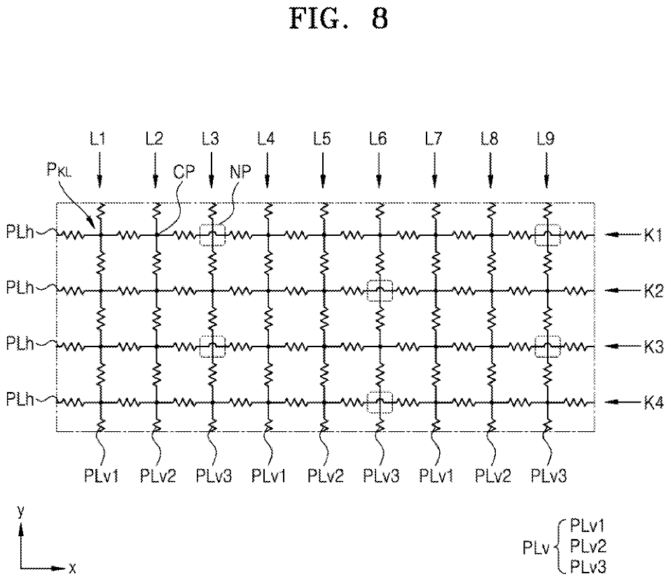

FIG. 7 is a schematic diagram showing a relationship between an emission area and a driving voltage line according to an embodiment, and FIG. 8 is a schematic diagram of an equivalent circuit schematically showing a connection relationship between a horizontal driving voltage line PLh and a vertical driving voltage line PLv shown in FIG. 7.

Referring to FIG. 7, the first emission area EA1, the second emission area EA2, and the third emission area EA3 may be disposed in one unit area UA. Unit areas UA (UA_{MN}) may be provided and repeatedly arranged to form a M×N matrix in the first direction (e.g., x-axis direction) and the second direction (e.g., y-axis direction). For example, the unit areas UA_{MN} may be arranged in rows M1, M2, M3, and M4 and columns N1, N2, N3, and N4. For example, the unit areas UA_{MN} may be disposed in M-th row and N-th column. Here, M and N may be natural numbers greater than 0.

In one unit area UA, the first emission area EA1 and the second emission area EA2 may be spaced apart from each other in the second direction (e.g., y-axis direction). The third emission area EA3 may be spaced apart from the first emission area EA1 and the second emission area EA2 in the first direction (e.g., x-axis direction).

In each unit area UA, respective locations (or positions) of the first emission area EA1 and the second emission area EA2 may be fixed, but a location (or position) of the third emission area EA3 may change. For example, the third emission areas EA3 may be arranged in a zigzag manner in the first direction (e.g., x-axis direction).

Third emission areas EA3 adjacent to each other along the second direction (e.g., y-axis direction) may be defined as a pixel group PG. In this regard, FIG. 7 shows that one pixel group PG includes two third emission areas EA3 adjacent to each other in the second direction (e.g., y-axis direction). Third emission areas EA3 belonging to the same pixel group PG and neighboring each other may be spaced apart from each other by a first distance d1, and third emission areas EA3 belonging to different pixel groups PG and neighboring each other may be spaced apart from each other by a second distance d2. The first distance d1 may be less than the second distance d2.

In a unit area UA, the first vertical driving voltage line PLv1, the second vertical driving voltage line PLv2, and the third vertical driving voltage line PLv3 may be spaced apart from each other in the first direction (e.g., x-axis direction). Unit areas UA forming a column in the second direction (e.g., y-axis direction) may share the same vertical driving voltage lines PLv.

In a unit area UA, a horizontal driving voltage line PLh extending in the first direction (e.g., x-axis direction) may be disposed. Unit areas UA forming a row in the first direction (e.g., x-axis direction) may share the same horizontal driving voltage lines PLh.

Contact holes CNT for forming a mesh structure by electrically connecting a horizontal driving voltage line PLh to vertical driving voltage lines PLv may be arranged. The contact holes CNT may include a first contact hole CNT1, a second contact hole CNT2, and a third contact hole CNT3. The horizontal driving voltage line PLh and the first vertical driving voltage line PLv1 may contact (or may electrically contact) each other through the first contact hole CNT1. The horizontal driving voltage line PLh and the second vertical driving voltage line PLv2 may contact (or may electrically contact) each other through the second contact hole CNT2. The horizontal driving voltage line PLh and the third vertical driving voltage line PLv3 may contact (or may electrically contact) each other through the third contact hole CNT3.

The first contact hole CNT1 and the second contact hole CNT2 may be spaced apart from the first emission area EA1, the second emission area EA2, and the third emission area EA3. However, the third contact hole CNT3 may overlap the third emission area EA3.

As described above, a spacing between neighboring third emission areas EA3 in the second direction (e.g., y-axis direction) may vary. Accordingly, the third emission areas EA3 may be arranged in a zigzag manner in the first direction (e.g., x-axis direction), and a relative position between the area where the horizontal driving voltage line PLh and the third vertical driving voltage line PLv3 intersect each other and a third emission area EA3 may vary.

For example, in a (1,1) unit area UA₁₁, a second intersection area CA2 where the horizontal driving voltage line PLh and the third vertical driving voltage line PLv3 intersect each other may be spaced apart from the center portion of the third emission area EA3 in a plan view. However, in a (2,1) unit area UA₂₁, a first intersection area CA1 where the horizontal driving voltage line PLh and the third vertical driving voltage line PLv3 intersect each other may be positioned approximately at the center portion of the third emission area EA3 in a plan view.

In case that the third contact hole CNT3 is positioned at the center portion of the third emission area EA3 in a plan view, an influence of the third contact hole CNT3 is approximately symmetrical with respect to the center portion of the third emission area EA3, and thus the emission characteristics of a pixel according to a viewing angle may be the same. However, in case that a contact hole CNT is spaced apart from the center portion of the third emission area EA3 in a plan view, the luminance and the like of a pixel may vary according to the viewing angle. Thus, according to embodiments, the third contact hole CNT3 may be disposed at the center portion of the third emission area EA3 only in case that the horizontal driving voltage line PLh and the third vertical driving voltage line PLv3 intersect each other in the third emission area EA3 in a plan view.

For example, in the (1,1) unit area UA₁₁, a second intersection area CA2 may be spaced apart from the center portion of the third emission area EA3, and thus a contact hole may be omitted. For example, in the second intersection area CA2, an insulating layer may cover (e.g., completely cover) the horizontal driving voltage line PLh, thereby separating the horizontal driving voltage line PLh from the third vertical driving voltage line PLv3. However, in a (2,1) unit area UA₂₁, the first intersection area CA1 may be positioned at the center portion of the third emission area EA3, and the third contact hole CNT3 may be disposed by overlapping the first intersection area CA1. Thus, the third contact hole CNT3 may be disposed approximately at the center portion of the third emission area EA3.

Because the third emission areas EA3 are repeatedly arranged in a certain pattern, an arrangement of the third contact holes CNT3 may also be repeated in a certain pattern. For example, as shown in FIG. 7, third contact holes CNT3 may be arranged in unit areas UA₁₂, UA₁₄, . . . arranged in even columns among unit areas arranged in a first row, and contact holes may be omitted in unit areas UA₁₁, UA₁₃, . . . arranged in odd columns among the unit areas arranged in the first row. The third contact hole CNT3 may be arranged in unit areas UA₂₁, UA₂₃, . . . arranged in odd columns among unit areas arranged in a second row, and contact holes may be omitted in unit areas UA₂₂, UA₂₄, . . . arranged in even columns among the unit areas arranged in the second row.

FIG. 8 schematically shows a connection relationship between a horizontal driving voltage line PLh and a vertical driving voltage line PLv. Referring to FIG. 8, horizontal driving voltage lines PLh and vertical driving voltage lines PLv may form a mesh structure by intersecting each other in the first direction (e.g., x-axis direction) and the second direction (e.g., y-axis direction).

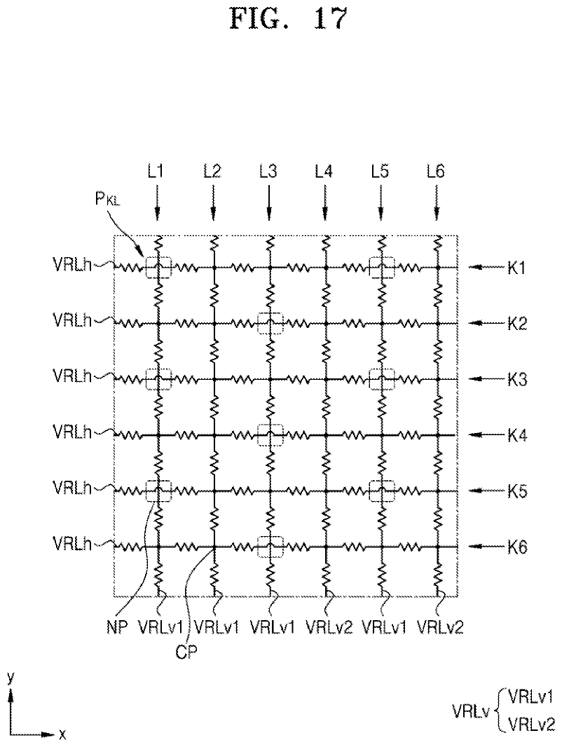

Intersections P_{KL} between the horizontal driving voltage lines PLh and the vertical driving voltage lines PLv may form a K×L matrix. For example, the intersections P_{KL} may be arranged in rows K1, K2, K3, K4, K5, and K6 and columns L1, L2, L3, L4, L5, L6, L7, L8, and L9. Sec, e.g., FIGS. 8 and 17, for example, the intersections P_{KL} may be disposed in K-th row and L-th column. Here, K and L may be natural numbers greater than 0.

Each of the intersections P_{KL} may be a connection point CP where intersecting wirings (or intersecting conductive layers) are electrically connected to each other, or a non-connection point NP where intersecting wirings are not connected to each other.

The connection points CP and the non-connection points NP may be arranged alternately in columns L3, L6, L9, . . . of multiples of 3. For example, a (1,3) intersection P₁₃ may be a non-connection point NP, a (2,3) intersection P₂₃ may be a connection point CP, a (3,3) intersection P₃₃ may be a non-connection point NP, and a (4,3) intersection P₄₃ may be a connection point CP.

Five connection points CP may be disposed between neighboring non-connection points NP in each row. For example, in a first row, a first non-connection point NP may be disposed at the (1,3) intersection P₁₃, a second non-connection point NP may be disposed at a (1,9) intersection P₁₉, and intersections P₁₄, P₁₅, P₁₆, P₁₇, and P₁₈ between the first non-connection point NP and the second non-connection point NP may all be connection points CP.

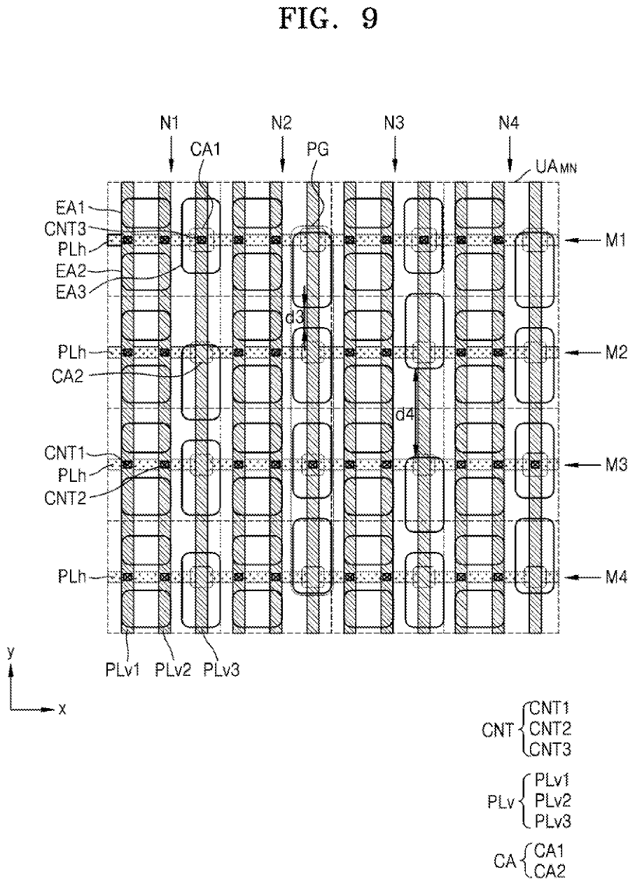

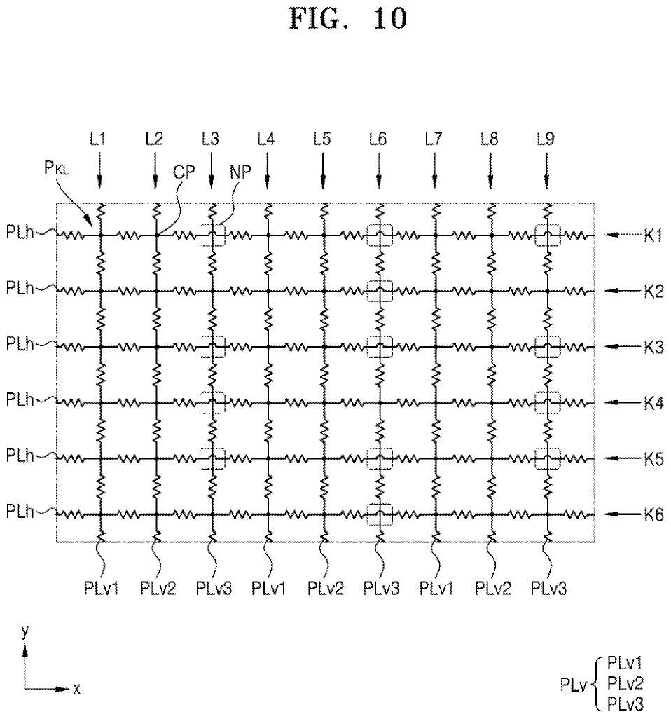

FIG. 9 is a schematic diagram showing a relationship between an emission area and a driving voltage line according to an embodiment, and FIG. 10 is a schematic diagram of an equivalent circuit schematically showing a connection relationship between a horizontal driving voltage line PLh and a vertical driving voltage line PLv shown in FIG. 9.

Referring to FIG. 9, the first emission area EA1, the second emission area EA2, and the third emission area EA3 may be disposed in one unit area UA. Unit areas UA (or UA_{MN}) may be provided and repeatedly arranged to form a M×N matrix in the first direction (e.g., x-axis direction) and the second direction (e.g., y-axis direction). Here, M and N may be natural numbers greater than 0. For example, the unit areas UAN may be arranged in rows M1, M2, M3, and M4 and columns N1, N2, N3, and N4. For example, the unit areas UA_{MN} may be disposed in M-th row and N-th column.

In each unit area UA, respective locations (or positions) of the first emission area EA1 and the second emission area EA2 may be fixed, but a location (or position) of the third emission area EA3 may change. For example, the third emission areas EA3 may be arranged in a zigzag manner in the first direction (e.g., x-axis direction).

Third emission areas EA3 adjacent to each other along the second direction (e.g., y-axis direction) may be defined as a pixel group PG. In this regard, FIG. 9 shows that one pixel group PG includes four third emission areas EA3 adjacent to one another in the second direction (e.g., y-axis direction). Third emission areas EA3 belonging to the same pixel group PG and neighboring each other may be spaced apart from each other by a third distance d3, and third emission areas EA3 belonging to different pixel groups PG and neighboring each other may be spaced apart from each other by a fourth distance d4. The third distance d3 may be less than the fourth distance d4.

In a unit area UA, the first vertical driving voltage line PLv1, the second vertical driving voltage line PLv2, and the third vertical driving voltage line PLv3 may be spaced apart from each other in the first direction (e.g., x-axis direction). Unit areas UA forming a column in the second direction (e.g., y-axis direction) may share the same vertical driving voltage lines PLv.

In a unit area UA, a horizontal driving voltage line PLh extending in the first direction (e.g., x-axis direction) may be disposed. Unit areas UA forming a row in the first direction (e.g., x-axis direction) may share the same horizontal driving voltage lines PLh.

Contact holes CNT for forming a mesh structure by electrically connecting horizontal driving voltage lines PLh to vertical driving voltage lines PLv may be arranged. The contact holes CNT may include a first contact hole CNT1, a second contact hole CNT2, and a third contact hole CNT3. The horizontal driving voltage line PLh and the first vertical driving voltage line PLv1 may contact (or may electrically contact) each other through the first contact hole CNT1. The horizontal driving voltage line PLh and the second vertical driving voltage line PLv2 may contact (or may electrically contact) each other through the second contact hole CNT2. The horizontal driving voltage line PLh and the third vertical driving voltage line PLv3 may contact (or may electrically contact) each other through the third contact hole CNT3.

The first contact hole CNT1 and the second contact hole CNT2 may be spaced apart from the first emission area EA1, the second emission area EA2, and the third emission area EA3. However, the third contact hole CNT3 may overlap the third emission area EA3.

For example, in a (1,1) unit area UA₁₁, a first intersection area CA1 where the horizontal driving voltage line PLh and the third vertical driving voltage line PLv3 intersect each other may be positioned approximately at the center portion of the third emission area EA3 in a plan view. However, in a (2,1) unit area UA₂₁, a second intersection area CA2 where the horizontal driving voltage line PLh and the third vertical driving voltage line PLv3 intersect each other may be spaced apart from the center portion of the third emission area EA3 in a plan view.

The third contact hole CNT3 may be disposed at the center portion of the third emission area EA3 only in case that the horizontal driving voltage line PLh and the third vertical driving voltage line PLv3 intersect each other in the third emission area EA3 in a plan view. For example, in a (1,1) unit area UA₁₁, the first intersection area CAL may be positioned approximately at the center portion of the third emission area EA3, and the third contact hole CNT3 may be disposed by overlapping the first intersection area CA1. Thus, the third contact hole CNT3 may be disposed approximately at the center portion of the third emission area EA3. For example, in the (2,1) unit area UA₂₁, a second intersection area CA2 may be spaced apart from the center portion of the third emission area EA3, and thus a contact hole may be omitted. For example, in the second intersection area CA2, an insulating layer may cover (e.g., completely cover) the horizontal driving voltage line PLh, thereby separating the horizontal driving voltage line PLh from the third vertical driving voltage line PLv3.

Because the third emission areas EA3 are repeatedly arranged in a certain pattern, an arrangement of the third contact holes CNT3 may also be repeated in a certain pattern. In this regard, FIG. 9 shows a third contact hole CNT3 disposed in the area where the horizontal driving voltage line PLh intersects the third vertical driving voltage line PLv3, in a (1,1) unit area UA₁₁, a (1,3) unit area UA₁₃, a (3,2) unit area UA₃₂, and a (3,4) unit area UA₃₄.

Referring to FIG. 10, horizontal driving voltage lines PLh and vertical driving voltage lines PLv may form a mesh structure by intersecting each other in the first direction (e.g., x-axis direction) and the second direction (e.g., y-axis direction).

Intersections P_{KL} between the horizontal driving voltage lines PLh and the vertical driving voltage lines PLv may form a K×L matrix. Each of the intersections P_{KL} may be a connection point CP where intersecting wirings (or intersecting conductive layers) are electrically connected to each other, or a non-connection point NP where intersecting wirings are not connected to each other.

Connection points CP and non-connection points NP may be arranged repeatedly in a certain pattern in the second direction (e.g., y-axis direction) in columns L3, L6, L9, . . . of multiples of 3. For example, three non-connection points NP may be arranged between connection points CP adjacent to each other in the second direction (e.g., y-axis direction). A (2,3) intersection P₂₃ and a (6,3) intersection P₆₃ may be connection points CP adjacent to each other in the second direction (e.g., y-axis direction), and intersections P₃₃, P₄₃, and P₅₃ between the (2,3) intersection P₂₃ and the (6,3) intersection P₆₃ may all be non-connection points NP.

Intersection P₁₃, P₁₆, P₁₉, P₃₃, . . . positioned in odd rows K1, K3, K5, . . . and columns L3, L6, L9, . . . of multiples of 3 may all be non-connected points NP. Five connection points CP may be arranged between non-connection points NP adjacent to each other in the first direction (e.g., x-axis direction) in even rows K2, K4, K6, . . . . For example, a (4,3) intersection P₄₃ and a (4,9) intersection P₄₉ may be non-connection points NP adjacent to each other in the first direction (e.g., x-axis direction), and intersection P₄₄, P₄₅, P₄₆, P₄₇, and P₄₈ between the (4,3) intersection P₄₃ and the (4,9) intersection P₄₉ may all be connection points CP.

FIGS. 4 through 10 illustrate driving voltage lines PL transmitting the driving voltage ELVDD, but embodiments are not limited thereto. Those of ordinary skill in the art will clearly understand that arrangement rules of contact holes and emission areas disclosed in embodiments form a mesh structure, and that an intersection area of horizontal and vertical wirings is applied to constant voltage lines that overlap or do not overlap an emission area in a pattern in which emission areas are arranged.

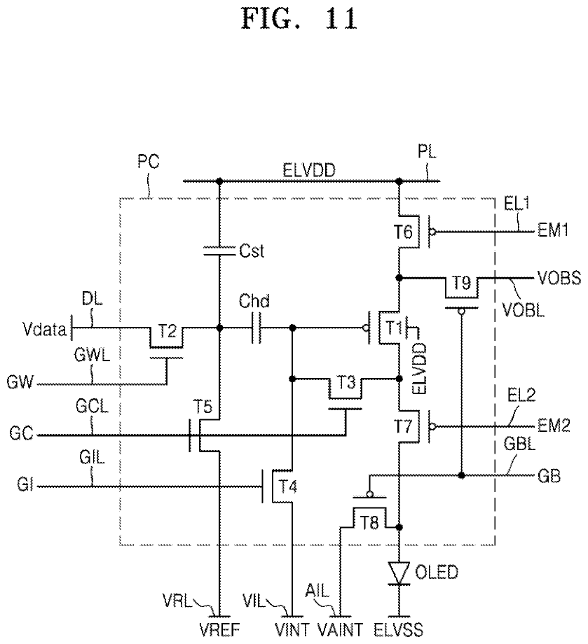

FIG. 11 is a schematic diagram of an equivalent circuit of a representative pixel PX included in a display apparatus according to an embodiment.

Referring to FIG. 11, the pixel PX may include a pixel circuit PC and an organic light-emitting diode OLED electrically connected to the pixel circuit PC.

The pixel circuit PC may include a first transistor T1, which is a driving transistor, and second, third, fourth, fifth, sixth, seventh, eighth, and ninth transistors T2, T3, T4, T5, T6, T7, T8, and T9, which are switching transistors. According to the type (e.g., P-type or N-type) of transistor and/or operating conditions thereof, a first terminal of each of the first through ninth transistors T1 through T9 may be a source terminal or a drain terminal, and a second terminal thereof may be a different terminal than the first terminal. For example, in case that the first terminal is a source terminal, the second terminal may be a drain terminal. According to an embodiment, the source terminal and the drain terminal may be interchangeably referred to as a source electrode and a drain electrode, respectively.

The pixel circuit PC may be connected to a first scan line GWL that transmits a first scan signal GW, a second scan line GIL that transmits a second scan signal GI, a third scan line GBL that transmits a third scan signal GB, a fourth scan line GCL that transmits a fourth scan signal GC, a first emission control line EL1 that transmits a first emission control signal EM1, a second emission control line EL2 that transmits a second emission control signal EM2, a data line DL that transmits a data signal Vdata, a driving voltage line PL that transmits a driving voltage ELVDD, a first initializing voltage line VIL that transmits a first initializing voltage VINT, a second initializing voltage line AIL that transmits a second initializing voltage VAINT, a reference voltage line VRL that transmits a reference voltage VREF, and a bias voltage line VOBL that transmits a bias voltage VOBS.

The first transistor T1 (e.g., driving transistor) may be connected between the driving voltage line PL and the organic light-emitting diode OLED. The first transistor T1 may be connected to the driving voltage line PL through the sixth transistor T6, and may be electrically connected to the organic light-emitting diode OLED through the seventh transistor T7. The first transistor T1 may receive a data signal according to a switching operation of the second transistor T2 and may supply a driving current to the organic light-emitting diode OLED.

The second transistor T2 (e.g., data write transistor) may be connected between the data line DL and the first transistor T1. The second transistor T2 may include a gate terminal connected to the first scan line GWL, a first terminal connected to the data line DL, and a second terminal connected to a first electrode of a hold capacitor Chd. The second transistor T2 may be turned on in response to the first scan signal GW received through the first scan line GWL, to perform a switching operation of transmitting the data signal Vdata received through the data line DL to the hold capacitor Chd.

The third transistor T3 (e.g., compensation transistor) may be connected between the gate terminal of the first transistor T1 and the second terminal of the first transistor T1. The third transistor T3 may be connected to the organic light-emitting diode OLED via the seventh transistor T7. The third transistor T3 may include a gate connected to the fourth scan line GCL, a first terminal connected to the gate terminal of the first transistor T1, and a second terminal connected to the second terminal of the first transistor T1. The third transistor T3 may be turned on in response to the fourth scan signal GC received through the fourth scan line GCL to diode-connect the first transistor T1, thereby compensating for a threshold voltage of the first transistor T1.

The fourth transistor T4 (e.g., first initialization transistor) may be connected between the gate terminal of the first transistor T1 and the first initializing voltage line VIL. The fourth transistor T4 may include a gate terminal connected to the second scan line GIL, a first terminal connected to the gate terminal of the first transistor T1, and a second terminal connected to the first initializing voltage line VIL. The fourth transistor T4 may be turned on in response to the second scan signal GI received through the second scan line GIL, to transmit the first initializing voltage VINT to the gate terminal of the first transistor T1 thereby initializing the gate voltage of the first transistor T1.

The fifth transistor T5 may be connected between the hold capacitor Chd and the storage capacitor Cst and the reference voltage VREF. The fifth transistor T5 may include a gate terminal connected to the fourth scan line GCL, a first terminal connected to the first electrode of the hold capacitor Chd and a second electrode of the storage capacitor Cst, and a second terminal connected to the reference voltage line VRL. The fifth transistor T5 may be turned on in response to the fourth scan signal GC received through the fourth scan line GCL thereby transmitting the reference voltage VREF to the first electrode of the hold capacitor Chd and the second electrode of the storage capacitor Cst.

The sixth transistor T6 (e.g., first emission control transistor) may be connected between the driving voltage line PL and the first terminal of the first transistor T1. The seventh transistor T7 (e.g., second emission control transistor) may be connected between the second terminal of the first transistor T1 and the organic light-emitting diode OLED. The sixth transistor T6 may include a gate terminal connected to the first emission control line EL1, a first terminal connected to the driving voltage line PL, and a second terminal connected to the first terminal of the first transistor T1. The seventh transistor T7 may include a gate terminal connected to the second emission control line EL2, a first terminal connected to the second terminal of the first transistor T1, and a second terminal connected to the organic light-emitting diode OLED.

The sixth transistor T6 and the seventh transistor T7 may be turned on according to the first emission control signal EM1 and the second emission control signal EM2, respectively, so that a driving current may flow to the organic light-emitting diode OLED.

The eighth transistor T8 (e.g., second initialization transistor) may be connected between the organic light-emitting diode OLED and the second initializing voltage line AIL. The eighth transistor T8 may include a gate terminal connected to the third scan line GBL, a first terminal connected to the second terminal of the seventh transistor T7 and the pixel electrode of the organic light-emitting diode OLED, and a second terminal connected to the second initializing voltage line AIL. The eighth transistor T8 may be turned on in response to the third scan signal GB received via the third scan line GBL to transmit the second initializing voltage VAINT to the pixel electrode of the organic light-emitting diode OLED and to initialize a voltage of the pixel electrode of the organic light-emitting diode OLED. According to an embodiment, different second initializing voltages VAINT may be supplied to different pixels PX according to the colors in which the pixels PX emit light.

The ninth transistor T9 may be connected between the bias voltage line VOBL and the first transistor T1. The ninth transistor T9 may include a gate terminal connected to the third scan line GBL, a first terminal connected to the first terminal of the first transistor T1, and a second terminal connected to the bias voltage line VOBL. The ninth transistor T9 may be turned on in response to the third scan signal GB received through the third scan line GBL to transmit the bias voltage VOBS to the first terminal of the first transistor T1.

The driving voltage ELVDD, the common voltage ELVSS, the first initializing voltage VINT, the second initializing voltage VAINT, the reference voltage VREF, and the bias voltage VOBS may be constant voltages without voltage change during one frame. The driving voltage line PL, the first initializing voltage line VIL, the second initializing voltage line AIL, the reference voltage line VRL, and the bias voltage line VOBL may be constant voltage lines for transmitting a constant voltage. These constant voltage lines may be formed in a mesh structure to reduce differences between light emission characteristics of pixels due to a voltage drop across a display area.

The storage capacitor Cst may include a first electrode connected to the driving voltage line PL, and a second electrode connected to the first electrode of the hold capacitor Chd and the second terminal of the second transistor T2. The storage capacitor Cst may maintain a voltage applied to the gate electrode of the first transistor T1, by storing and maintaining a voltage corresponding to a difference between voltages respectively supplied to end portions (e.g., opposite end portions) of the first electrode and the second electrode.

The hold capacitor Chd may include a first electrode connected to the second terminal of the second transistor T2 and the second electrode of the storage capacitor Cst, and a second electrode connected to the gate terminal of the first transistor T1. The hold capacitor Chd may transmit the data signal Vdata to the gate terminal of the first transistor T1 by using a potential difference between the first and second electrodes.

The organic light-emitting diode OLED may include the pixel electrode (e.g., an anode) and an opposite electrode (e.g., a cathode) facing the pixel electrode, and the opposite electrode may receive the common voltage ELVSS. The organic light-emitting diode OLED may receive the driving current from the first transistor T1 and emit light in a certain color, thereby displaying an image.

Some of the transistors of the pixel circuit PC may be P-type transistors and others may be N-type transistors, but embodiments are not limited thereto. In FIG. 11, the second transistor T2, the third transistor T3, the fourth transistor T4, and the fifth transistor T5 may be N-type transistors, and the first transistor T1, the sixth transistor T6, the seventh transistor T7, the eighth transistor T8, and the ninth transistor T9 may be P-type transistors.

The N-type transistors may be oxide thin film transistors, and the P-type transistors may be silicon thin film transistors. For example, an active pattern layer (e.g., semiconductor layer) included in an N-type transistor may include an inorganic semiconductor (e.g., amorphous silicon or polysilicon) or an organic semiconductor. An active pattern layer (e.g., semiconductor layer) included in a P-type transistor may include amorphous silicon, polysilicon, or the like.

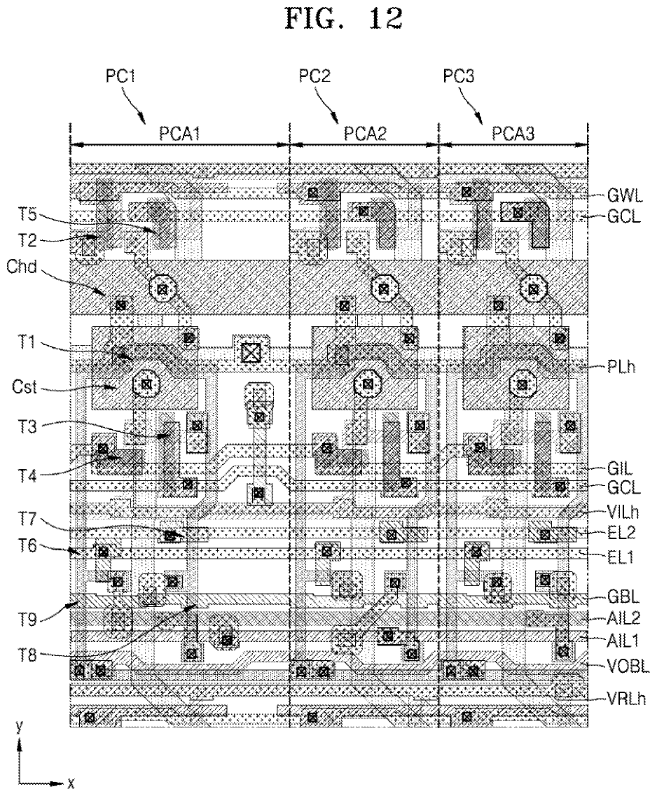

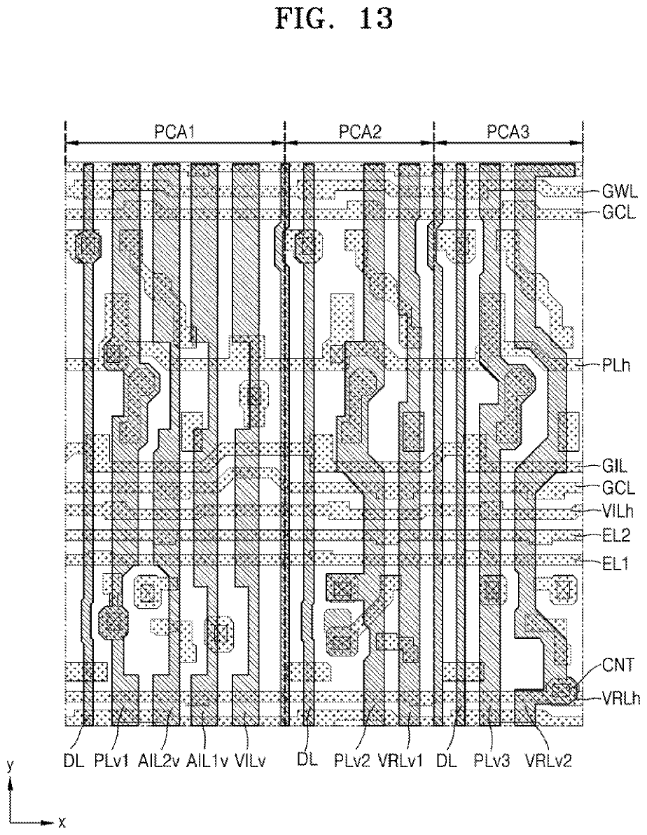

FIG. 12 is a schematic layout view illustrating a display apparatus according to an embodiment, and FIG. 13 is a schematic plan view illustrating an arrangement of a first conductive layer and a second conductive layer of a display apparatus according to an embodiment. FIGS. 12 and 13 may correspond to layout views of the pixel PX shown in FIG. 11. Hereinafter, identical devices disposed in similar positions in the first, second, and third pixel circuits PC1, PC2, and PC3 will not be described separately.

Referring to FIGS. 12 and 13, the first through ninth transistors T1 through T9 may be disposed in each of the first pixel area PCA1, the second pixel area PCA2, and the third pixel area PCA3. A semiconductor layer of each of the first through ninth transistors T1 through T9 may include a channel region and a source region and a drain region on sides (e.g., opposite sides) of the channel region. The channel region of the first transistor T1 may be formed to be long (or extended) by being curved, so that the driving range of the gate voltage applied to the gate electrode may be expanded. In some cases, a source region or a drain region may be interpreted as a source electrode or drain electrode of a transistor. For example, a source electrode and a drain electrode of the first transistor T1 may correspond to a source region and a drain region doped with impurities near the channel region, respectively.

The first scan line GWL, the second scan line GIL, the third scan line GBL, the fourth scan line GCL, the first emission control line EL1, the second emission control line EL2, the first horizontal initializing voltage line VILh, the horizontal driving voltage line PLh, the (2-1)th initializing voltage line AIL1, the (2-2)th initializing voltage line AIL2, the bias voltage line VOBL, and a horizontal reference voltage line VRLh may each extend in the first direction (e.g., x-axis direction). The first horizontal initializing voltage line VILh, the horizontal driving voltage line PLh, the (2-1)th initializing voltage line AIL1, the (2-2)th initializing voltage line AIL2, the bias voltage line VOBL, and the horizontal reference voltage line VRLh may be horizontal wirings (or horizontal conductive layer) that are electrically connected to their corresponding vertical wirings to form a mesh structure.

Some of the wirings each extending in the first direction (e.g., x-axis direction) may each include an upper wiring and a lower wiring arranged on different layers. The upper wiring and the lower wiring may overlap each other, and one or more insulating layers may be disposed on the upper wiring and the lower wiring. The upper wiring and the lower wiring may be electrically connected to each other through a contact hole defined in the one or more insulating layers.

The gate electrode of the second transistor T2 may be portions protruding from the first scan line GWL. The gate electrode of the third transistor T3 may be portions protruding from the fourth scan line GCL. The gate electrode of the fourth transistor T4 may be portions of the second scan line GIL that intersect the semiconductor layer of the fourth transistor T4. The gate electrode of the fifth transistor T5 may be portions protruding from the fourth scan line GCL.

Each of the gate electrodes of the second transistor T2, the third transistor T3, the fourth transistor T4, and the fifth transistor T5 may include an upper gate electrode and a lower gate electrode disposed opposite to each other with the semiconductor layer interposed therebetween. The lower gate electrode may overlap an active region of the semiconductor layer thereby preventing device characteristics from changing due to external light incident from the side of a substrate.

The gate electrode of the first transistor T1 may be formed in an island type. The first electrode of the storage capacitor Cst may overlap the gate electrode of the first transistor T1. For example, the gate electrode of the first transistor T1 may be the second electrode of the storage capacitor Cst (see FIG. 2).

The gate electrode of the sixth transistor T6 may be portions of the first emission control line EL1 that intersect the semiconductor layer of the sixth transistor T6. The gate electrode of the seventh transistor T7 may be portions of the second emission control line EL2 that intersect the semiconductor layer of the seventh transistor T7. The gate electrode of the eighth transistor T8 and the gate electrode of the ninth transistor T9 may be portions of the third scan line GBL intersecting the semiconductor layer.

The hold capacitor Chd may be disposed between the first transistor T1 and the second transistor T2. The hold capacitor Chd may extend in the first direction (e.g., x-axis direction) over the first pixel area PCA1, the second pixel area PCA2, and the third pixel area PCA3.

In the first pixel area PCA1, the data line DL, the first vertical driving voltage line PLv1, the (2-1)th vertical initializing voltage line AIL1v, the (2-2)th vertical initializing voltage line AIL2v, and the first vertical initializing voltage line VILv may each extend in the second direction (e.g., y-axis direction).

In the second pixel area PCA2, the data line DL, the second vertical driving voltage line PLv2, and the first vertical reference voltage line VRLv1 may each extend in the second direction (e.g., y-axis direction).

In the third pixel area PCA3, the data line DL, the third vertical driving voltage line PLv3, and the second vertical reference voltage line VRLv2 may each extend in the second direction (e.g., y-axis direction).

The first vertical driving voltage line PLv1, the (2-1)th vertical initializing voltage line AIL1v, the (2-2)th vertical initializing voltage line AIL2v, the first vertical initializing voltage line VILv, the first vertical reference voltage line VRLv1, and the second vertical reference voltage line VRLv2 may be vertical wirings (or vertical conductive layer) that are electrically connected to their corresponding horizontal wirings to form a mesh structure.

The first vertical driving voltage line PLv1, the second vertical driving voltage line PLv2, and the third vertical driving voltage line PLv3 may be disposed on a different layer from a layer on which the horizontal driving voltage line PLh is disposed. The horizontal driving voltage line PLh, the first vertical driving voltage line PLv1, the second vertical driving voltage line PLv2, and the third vertical driving voltage line PLv3 may be electrically connected to one another through a contact hole thereby forming a mesh structure for transmitting the driving voltage ELVDD.

The (2-1)th initializing voltage line AIL1 may be arranged on a different layer from the layer on which the (2-1)th vertical initializing voltage line AIL1v is arranged. The (2-1)th initializing voltage line AIL1 and the (2-1)th vertical initializing voltage line AIL1v may be electrically connected to each other through a contact hole thereby forming a mesh structure for transmitting a (2-1)th initializing voltage. Likewise, the (2-2)th initializing voltage line AIL2 and the (2-2)th vertical initializing voltage line AIL2v may be electrically connected to each other through a contact hole thereby forming a mesh structure for transmitting a (2-2)th initializing voltage. The (2-1)th initializing voltage applied to the (2-1)th initializing voltage line AIL1 and the (2-1)th vertical initializing voltage line AIL1v may be different from the (2-2)th initializing voltage applied to the (2-2)th initializing voltage line AIL2 and the (2-2)th vertical initializing voltage line AIL2v.

The first horizontal initializing voltage line VILh may be arranged on a different layer from the layer on which the first vertical initializing voltage line VILv is arranged. The first horizontal initializing voltage line VILh and the first vertical initializing voltage line VILv may be electrically connected to each other through a contact hole thereby forming a mesh structure for transmitting the first initializing voltage Vint.

The horizontal reference voltage line VRLh may be disposed on a different layer from a layer on which the first vertical reference voltage line VRLv1 and the second vertical reference voltage line VRLv2 are disposed. The horizontal reference voltage line VRLh and the first vertical reference voltage line VRLv1 and the second vertical reference voltage line VRLv2 may be electrically connected to one another through a contact hole thereby forming a mesh structure for transmitting the reference voltage VREF.

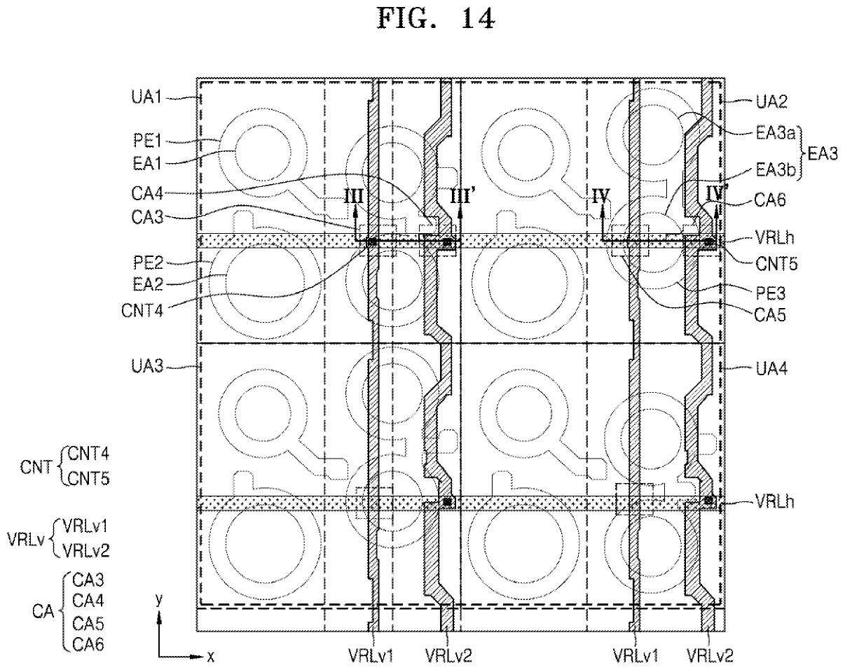

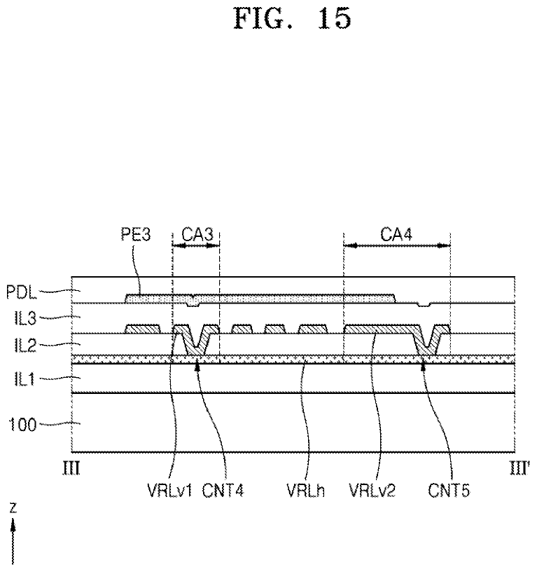

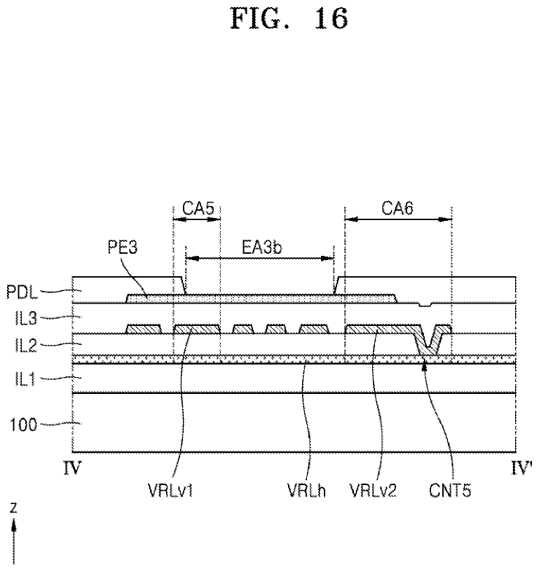

FIG. 14 is a schematic plan view illustrating a relationship between a pixel electrode and a reference voltage line according to an embodiment, FIG. 15 is a schematic cross-sectional view showing a cross-section taken along line III-III′ of the display apparatus shown in FIG. 14, and FIG. 16 is a schematic cross-sectional view showing a cross-section taken along line IV-IV′ of the display apparatus shown in FIG. 14.

Referring to FIGS. 14, 15, and 16, a first insulating layer IL1 having a multi-layer structure may be disposed on the substrate 100. For example, circuit elements forming the first, second, and third pixel circuits PC1, PC2, and PC3 may be disposed between insulating layers included in the first insulating layer IL1.

The horizontal reference voltage line VRLh extending in the first direction (e.g., x-axis direction) may be disposed over the first insulating layer IL1, and a second insulating layer IL2 may be disposed over the first insulating layer IL1 to cover the horizontal reference voltage line VRLh.

The vertical reference voltage line VRLv extending in the second direction (e.g., y-axis direction) may be disposed over the second insulating layer IL2. The vertical reference voltage line VRLv may include the first vertical reference voltage line VRLv1 and the second vertical reference voltage line VRLv2. A third insulating layer IL3 may be disposed over the second insulating layer IL2 to cover the vertical reference voltage line VRLv.

First, second, and third pixel electrodes PE1, PE2, and PE3 may be disposed over the third insulating layer IL3. The first pixel electrode PE1 may be electrically connected to the first pixel circuit PC1, the second pixel electrode PE2 may be electrically connected to the second pixel circuit PC2, and the third pixel electrode PE3 may be electrically connected to the third pixel circuit PC3.

The first insulating layer IL1 may include an inorganic insulating material and/or an organic insulating material. Each of the second insulating layer IL2 and the third insulating layer IL3 may include an organic insulating material. The inorganic insulating material may include silicon oxide, silicon nitride, or silicon oxynitride. The organic insulating material may include a commercial polymer such as benzocyclobutene (BCB), hexamethyldisiloxane (HMDSO), polymethyl methacrylate (PMMA) or polystyrene (PS), a polymer derivative having a phenol-based group, an acrylic-based polymer, an imide-based polymer such as polyimide, an aryl ether-based polymer, an amide-based polymer, a fluorine-based polymer, a p-xylene-based polymer, a vinyl alcohol-based polymer, or the like.

A pixel definition layer PDL may be disposed over the third insulating layer IL3 to cover the first, second, and third pixel electrodes PE1, PE2, and PE3. First, second, and third emission areas EA1, EA2, and EA3 may be defined by openings defined in the pixel definition layer PDL. In the first, second, and third emission areas EA1, EA2, and EA3, emission layers of organic light-emitting diodes respectively connected to the first, second, and third pixel circuits PC1, PC2, and PC3 may be disposed. The pixel definition layer PDL may include an organic insulating material, such as polyimide, polyamide, acryl resin, benzocyclobutene, hexamethyldisiloxane (HMDSO), or phenol resin.

Each of the first, second, and third emission areas EA1, EA2, and EA3 may correspond to respective portions of the first, second, and third pixel electrodes PE1, PE2, and PE3, respectively. The first emission area EA1, the second emission area EA2, and the third emission area EA3 may have different areas.

The third emission area EA3 may include a first sub-emission area EA3a and a second sub-emission area EA3b that are spaced apart from each other. The third pixel electrode PE3 may include two sub-electrodes connected to the same third pixel circuit PC3, and the first sub-emission area EA3a and the second sub-emission area EA3b may correspond to respective portions of the two sub-electrodes.

In a plan view, each of the first, second, and third emission areas EA1, EA2, and EA3 may have a shape such as a polygon (e.g., a rectangle or an octagon), a circle, or an oval. Examples of the polygon may also include a shape of which corners (e.g., vertexes) are rounded.

The first emission area EA1, the second emission area EA2, and the third emission area EA3 may be disposed in a single unit area UA. Unit areas UA may be provided and repeatedly arranged to form a matrix in the first direction (e.g., x-axis direction) and the second direction (e.g., y-axis direction). In this regard, FIG. 14 shows first, second, third, and fourth unit areas UA1, UA2, UA3, and UA4 forming a 2×2 matrix.

In each unit area UA, respective locations (or positions) of the first emission area EA1 and the second emission area EA2 may be fixed, but a location (or position) of the third emission area EA3 may change. For example, the third emission areas EA3 may be arranged in a zigzag manner in the first direction (e.g., x-axis direction). For example, the first sub-emission areas EA3a and the second sub-emission areas EA3b may be arranged in a zigzag manner in the first direction (e.g., x-axis direction).

In a unit area UA, one or more vertical reference voltage lines VRLv each extending in the second direction (e.g., y-axis direction) may be formed. For example, the first vertical reference voltage line VRLv1 and the second vertical reference voltage line VRLv2 may be disposed within each unit area UA. In each unit area UA, a horizontal reference voltage line VRLh extending in the first direction (e.g., x-axis direction) may be formed.

The first vertical reference voltage line VRLv1 and the second vertical reference voltage line VRLv2 may partially overlap the third pixel electrode PE3.

Contact holes CNT for forming a mesh structure by electrically connecting the horizontal reference voltage line VRLh to the vertical reference voltage line VRLv may non-overlap the first, second, and third emission areas EA1, EA2, and EA3. For example, the contact holes CNT may be spaced apart from the first, second, and third emission areas EA1, EA2, and EA3.

For example, the horizontal reference voltage line VRLh and the first vertical reference voltage line VRLv1 may contact (or may electrically contact) each other through a fourth contact hole CNT4 defined in the second insulating layer IL2. The fourth contact hole CNT4 may not overlap the first, second, and third emission areas EA1, EA2, and EA3.

The horizontal reference voltage line VRLh and the second vertical reference voltage line VRLv2 may contact (or may electrically contact) each other through a fifth contact hole CNT5 defined in the second insulating layer IL2. The fifth contact hole CNT5 may not overlap the first, second, and third emission areas EA1, EA2, and EA3.

A fourth intersection area CA4 and a sixth intersection area CA6, where the second vertical reference voltage line VRLv2 intersects the horizontal reference voltage line VRLh, may be disposed outside the third emission area EA3 such that the fourth intersection area CA4 and the sixth intersection area CA6 may not overlap the third emission area EA3. The second vertical reference voltage line VRLv2 may have a curved shape so that the fourth intersection area CA4 and the sixth intersection area CA6 may not overlap the third emission area EA3.

Because the third emission areas EA3 is arranged in a zigzag manner in the first direction (e.g., x-axis direction), a relative position between the area where the first vertical reference voltage line VRLv1 and the horizontal reference voltage line VRLh intersect each other and the third emission area EA3 may vary. In some unit areas, the area where the first vertical reference voltage line VRLv1 and the horizontal reference voltage line VRLh intersect each other may overlap the third emission area EA3, and, in other unit areas, the area where the first vertical reference voltage line VRLv1 and the horizontal reference voltage line VRLh intersect each other may not overlap the third emission area EA3.

For example, in the first unit area UA1, the third intersection area CA3 where the first vertical reference voltage line VRLv1 intersects the horizontal reference voltage line VRLh may not overlap the third emission area EA3. The fourth contact hole CNT4 via which the horizontal reference voltage line VRLh contacts (or electrically contacts) the first vertical reference voltage line VRLv1 may be positioned in the third intersection area CA3. The fourth contact hole CNT4 may be defined in the second insulating layer IL2.

However, in the second unit area UA2, the fifth intersection area CA5 where the first vertical reference voltage line VRLv1 intersects the horizontal reference voltage line VRLh may overlap the second sub-emission area EA3b. For example, the fifth intersection area CA5 may be spaced apart from a center portion of the second sub-emission area EA3b. No contact holes may be disposed in the fifth intersection area CA5. In the fifth intersection area CA5, the second insulating layer IL2 may cover the horizontal reference voltage line VRLh and may separate the horizontal reference voltage line VRLh from the first vertical reference voltage line VRLv1 in a thickness direction (e.g., z-axis direction).

In case that third emission areas EA3 are repeatedly arranged in a certain pattern, the fourth contact hole CNT4 via which the horizontal reference voltage line VRLh contacts (or electrically contacts) the first vertical reference voltage line VRLv1 may also be repeatedly arranged in a certain pattern.

FIG. 17 is a schematic diagram of an equivalent circuit schematically showing a connection relationship between a horizontal reference voltage line VRLh and a vertical reference voltage line VRLv shown in FIG. 14.

Referring to FIG. 17, horizontal reference voltage lines VRLh and vertical reference voltage lines VRLv may form a mesh structure by intersecting each other in the first direction (e.g., x-axis direction) and the second direction (e.g., y-axis direction).

Intersections P_{KL} between the horizontal reference voltage lines VRLh and the vertical reference voltage lines VRLv may form a K×L matrix. Each of the intersections P_{KL} may be a connection point CP where intersecting wirings are electrically connected to each other, or a non-connection point NP where intersecting wirings are not connected to each other.

The connection points CP and the non-connection points NP may be arranged alternately in odd-numbered columns L1, L3, L5, . . . . For example, a (1,1) intersection Pu may be a non-connection point NP, a (2,1) intersection P₂₁ may be a connection point CP, and a (3,1) intersection P₃₁ may be a non-connection point NP.

Three connection points CP may be disposed between neighboring non-connection points NP in each row. For example, in a first row, a first non-connection point NP may be disposed at the (1,1) intersection P₁₁, a second non-connection point NP may be disposed at a (1,5) intersection P₁₅, and intersections P₁₂, P₁₃, and P₁₄ between the first non-connection point NP and the second non-connection point NP may all be connection points CP.

FIGS. 14 through 17 illustrate reference voltage lines VRL transmitting the reference voltage VREF, but embodiments are not limited thereto. Those of ordinary skill in the art will clearly understand that embodiments form a mesh structure and that an intersection area of horizontal and vertical wirings (or horizontal and vertical conductive layers) is applied to constant voltage lines (e.g., the driving voltage line PL, the first initializing voltage line VIL, and the second initializing voltage line AIL) that overlap or do not overlap an emission area in a pattern in which emission areas are arranged.

According to embodiments as described above, a display apparatus that provides a high-quality image by reducing a difference between emission characteristics of pixels may be realized. However, the scope of the disclosure is not limited thereto.

In concluding the detailed description, those skilled in the art will appreciate that many variations and modifications may be made to the embodiments without substantially departing from the principles and spirit and scope of the disclosure. Therefore, the disclosed embodiments are used in a generic and descriptive sense only and not for purposes of limitation.

What is claimed is:

1. A display apparatus comprising:
a pixel electrode in which an emission area is defined;
a first horizontal conductive layer extending in a first direction;
a first vertical conductive layer extending in a second direction intersecting the first direction, and intersecting the first horizontal conductive layer;
a second vertical conductive layer extending in the second direction and intersecting the first horizontal conductive layer; and
an insulating layer disposed between the first horizontal conductive layer and the first vertical conductive layer and between the first horizontal conductive layer and the second vertical conductive layer, wherein
a first contact hole through which the first vertical conductive layer contacts the first horizontal conductive layer is defined in the insulating layer, and
the first contact hole is spaced apart from the emission area.

2. The display apparatus of claim 1, wherein, in an area where the first horizontal conductive layer and the second vertical conductive layer intersect each other, the insulating layer covers the first horizontal conductive layer.

3. The display apparatus of claim 1, wherein an area where the first horizontal conductive layer and the second vertical conductive layer intersect each other is spaced apart from a center portion of the emission area.

4. The display apparatus of claim 1, further comprising:
a second horizontal conductive layer extending in the first direction and intersecting the first vertical conductive layer and the second vertical conductive layer, wherein
a second contact hole through which the second horizontal conductive layer contacts the second vertical conductive layer is defined in the insulating layer, and
the second contact hole is spaced apart from the emission area.

5. The display apparatus of claim 4, wherein
a third contact hole through which the second horizontal conductive layer contacts the first vertical conductive layer is defined in the insulating layer, and
the third contact hole is spaced apart from the emission area.

6. The display apparatus of claim 4, wherein the first horizontal conductive layer, the second horizontal conductive layer, the first vertical conductive layer, and the second vertical conductive layer form a mesh structure.

7. The display apparatus of claim 6, wherein a constant voltage is applied to the mesh structure.

8. The display apparatus of claim 4, wherein
the emission area comprises a first sub-emission area and a second sub-emission area, and
the second contact hole is disposed between the first sub-emission area and the second sub-emission area.

9. The display apparatus of claim 1, wherein
each of the emission area and the pixel electrode is provided in plurality, and
each of pixel groups including two or more emission areas are spaced apart from each other in the second direction.

10. The display apparatus of claim 9, wherein
emission areas, which belong to a same pixel group and are adjacent to each other, are arranged to be spaced apart from each other by a first distance,
emission areas, which belong to different pixel groups and are adjacent to each other, are spaced apart from each other by a second distance, and
the first distance is less than the second distance.

11. The display apparatus of claim 1, wherein
the pixel electrode is provided in plurality, and
a plurality of pixel electrodes are arranged in a zigzag manner in the first direction.

12. A display apparatus comprising:
a first pixel electrode in which a first emission area is defined;
a second pixel electrode spaced apart from the first pixel electrode in a first direction and in which a second emission area is defined;
a first horizontal conductive layer extending in the first direction and intersecting the first emission area and the second emission area;
a first vertical conductive layer extending in a second direction intersecting the first direction, overlapping the first emission area, and intersecting the first horizontal conductive layer;
a second vertical conductive layer extending in the second direction, overlapping the second emission area, and intersecting the first horizontal conductive layer; and
an insulating layer disposed between the first horizontal conductive layer and the first vertical conductive layer and between the first horizontal conductive layer and the second vertical conductive layer, wherein
a first contact hole through which the first vertical conductive layer contacts the first horizontal conductive layer is defined in the insulating layer, and
the first contact hole is disposed at a center portion of the first emission area.

13. The display apparatus of claim 12, wherein
an area where the first horizontal conductive layer and the second vertical conductive layer intersect each other is spaced apart from a center portion of the second emission area, and
in the area where the first horizontal conductive layer and the second vertical conductive layer intersect each other, the insulating layer covers the first horizontal conductive layer.

14. The display apparatus of claim 12, further comprising:
a third pixel electrode spaced apart from the first pixel electrode in the second direction and in which a third emission area is defined; and
a second horizontal conductive layer extending in the first direction, overlapping the third emission area, and intersecting the first vertical conductive layer.

15. The display apparatus of claim 14, wherein
an area where the second horizontal conductive layer and the first vertical conductive layer intersect each other is spaced apart from a center portion of the third emission area, and
in the area where the second horizontal conductive layer and the first vertical conductive layer intersect each other, the insulating layer covers the second horizontal conductive layer.

16. The display apparatus of claim 14, further comprising:
a fourth pixel electrode spaced apart from the second pixel electrode in the second direction and in which a fourth emission area overlapping the second horizontal conductive layer is defined, wherein
a second contact hole through which the second vertical conductive layer contacts the second horizontal conductive layer is defined in the insulating layer, and
the second contact hole is disposed at a center portion of the fourth emission area.

17. The display apparatus of claim 16, wherein
the first pixel electrode and the third pixel electrode are spaced apart from each other by a first distance in the second direction,
the second pixel electrode and the fourth pixel electrode are spaced apart from each other by a second distance in the second direction, and
the first distance and the second distance are different from each other.

18. The display apparatus of claim 12, wherein the first pixel electrode and the second pixel electrode are arranged in a zigzag manner in the first direction.

19. The display apparatus of claim 14, wherein the first horizontal conductive layer, the second horizontal conductive layer, the first vertical conductive layer, and the second vertical conductive layer form a mesh structure.

20. The display apparatus of claim 19, wherein a constant voltage is applied to the mesh structure.
